(19) United States
(12) Patent Application Publication
(10) Pub. No.: US 2026/0067122 A1
(43) Pub. Date: Mar. 5, 2026

(54) 5G OVER COAXIAL COEXISTENCE WITH DOCSIS SYSTEMS AND METHODS

(71) Applicant: CHARTER COMMUNICATIONS OPERATING, LLC, St. Louis, MO (US)

(72) Inventors: Ramneek BALI, Aurora, CO (US); Manish JINDAL, Lone Tree, CO (US); Gary KOERPER, Castle Pines, CO (US); Kamran YOUSUF, Centennial, CO (US); Nikhil Attuvaliyil MURALEEDHARAN, Castlerock, CO (US); Manthan A. SHAH, Lone Tree, CO (US)

(73) Assignee: CHARTER COMMUNICATIONS OPERATING, LLC, St. Louis, MO (US)

(21) Appl. No.: 18/818,524

(22) Filed: Aug. 28, 2024

(51) Int. Cl. H04L 12/28; H03F 3/189

(52) U.S. Cl. CPC H04L 12/2801; H03F 3/189

(57) ABSTRACT

A network architecture and methods involving the same. The network architecture is configured to transmit a coexisting signal of both a Data Over Cable Services Interface Specification (DOCSIS) signal and a 5G signal, the architecture including a node apparatus that includes a Distributed Unit (DU); and a Radio Unit (RU) in communication with the DU, and the architecture includes a customer premises equipment (CPE) apparatus.

### COPYRIGHT

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### TECHNOLOGICAL FIELD

The present disclosure relates generally to the field of data networks and wireless devices, and specifically in one exemplary aspect to an architecture which provides high-speed data service in a content delivery network.

### BACKGROUND

Data communication services are now ubiquitous throughout user premises (e.g., home, office, vehicles, and even larger venues such as e.g., sports arenas, conference or convention centers, hotels, concert halls, airports, etc.). Such data communication services may be provided via a managed or unmanaged network. For instance, a typical home has services provided by one or more network service providers via a managed network such as a cable or satellite network. These services may include content delivery (e.g., linear television, on-demand content, personal or cloud DVR, “start over”, etc.), as well as so-called “over the top” delivery of third-party content. Similarly, Internet and telephony access is also typically provided, and may be bundled with the aforementioned content delivery functions into subscription packages, which are increasingly becoming more user- or premises-specific in their construction and content. Such services are also increasingly attempting to adopt the paradigm of “anywhere, anytime”, so that users (subscribers) can access the desired services (e.g., watching a movie) via a number of different receiving and rendering platforms, such as in different rooms of their houses, on their mobile devices while traveling, etc.

Issues with Existing Architecture and Services

As user appetite for enhanced data rates, mobility and diversity of services has increased over time, service providers have sought new technologies and paradigms for service delivery to compensate. In the case of cable networks, only so much expansion or enhancement is possible under traditional technology models (e.g., use of 800 MHz of spectral bandwidth with limited upstream bandwidth, modulation schemes, DOCSIS protocols, etc.), and even where such enhancement is possible, significant capital and R&D (research and development) expenditures are required to upgrade or adapt these existing technologies and infrastructure to the new required levels of performance.

As a simple example of the foregoing, consider a multi-dwelling unit (MDU) served by an existing hybrid fiber coax (HFC) network topology (see discussion of FIGS. 2 and 3 below). The network will typically utilize optical fiber (and/or coaxial cable) to deliver data to a network node, which then converts the optical domain data to RF (radio frequency) signals for transmission over the existing coaxial cable distribution network and to the served customers at the edge of the network (including the aforementioned MDU, which as most legacy structures, is internally wired with coaxial cable serving each individual dwelling unit therein, with the owner of the MDU retaining ownership of the cable installed by the multiple systems operator (MSO) and hence representing a “sunk cost” investment to the MSO). As customers demand increased levels of service (high data rates, more features, etc.) in order to maintain their loyalty/subscription in the face of competing services such as cellular data, fiber, satellite, etc., the cable MSO is often faced with the daunting prospect of upgrading the infrastructure serving such MDUs, which may include addition of fixed wireless access (FWA) infrastructure, replacing of miles of coaxial cable with optical fiber, and similar.

For instance, to achieve certain capacity targets (e.g., 10 Gbps) over such infrastructure, increased use of optical fiber is needed in certain parts of the infrastructure. Under current HFC network design, services are provided to users via a coaxial cable “drop” to their premises, and groups of such premises are served by common tap-off points or nodes within the larger architecture (see discussion of cable systems supra). Individual premises “tap off” the cabling or other infrastructure from each node and, depending on their geographic placement and other considerations, may require utilization of a number of different amplification units in order to maintain sufficient signal strength out to the most distant (topology-wise) premises in the system. For instance, a common description of how many amplifier stages are used between a source node and premises is “N+i”, where i=the number of amplifier stages between the source node and the premises. For instance, N=0 refers to the situation where no amplifiers are used, and N+3 refers to use of three (3) amplifiers. In some extant cable/HFC systems in operation, values of i may be as high as seven (7); i.e., N+7, such as for service to rural areas.

Use of such amplifier stages introduces some limitations on the data rates or bandwidth (both downstream—i.e., toward the client premises; and upstream—i.e., from the client premises) achievable by such systems. In effect, such systems are limited in maximum bandwidth/data rate, due in part to the design of the amplifiers; for example, they are typically designed to provide services primarily in the downstream direction (with much lower upstream bandwidth via so-called “OOB” or out-of-band RF channels providing highly limited upstream communication).

Cable modem or DOCSIS-compliant systems utilize DOCSIS QAMs (RF channels) for enhanced upstream bandwidth capability such as for Internet services, but even such technologies are in their current incarnations significantly limited in capability, and moreover have limited flexibility in the allocation of downstream versus upstream bandwidth, especially dynamically. For example, based on the DOCSIS protocols utilized for e.g., a coaxial infrastructure available in the aforementioned MDU served within a managed HFC network, throughput availability for downstream and upstream is in effect “hard-wired” based on how much of an available amount of spectrum is reserved for each direction. Because of this hard-wired availability, as well as the use of the aforementioned taps and amplifier stages, upstream throughput is limited in the foregoing HFC network.

One way of achieving higher data rates may require replacement of such amplifier stages (and supporting coaxial cabling) with other mediums such as optical fiber (sometimes referred to as going “fiber deep”, which can provide for example higher bandwidth, lower loss, and symmetric operation), microwave dishes at rooftop, and Ethernet cable (which can also provide symmetric operation), including going all the way back to an N+0 configuration throughout the entire network. However, replacement of literally tens of thousands of amplifiers and thousands of miles of cabling with optical fiber or the like is prohibitively expensive, and can take years.

Higher data rates may be achieved by implementation of DOCSIS 4.0 protocols; this version of the DOCSIS standard supports e.g., two (2) modes of use: (i) extended spectrum, without full duplex (which means separate allocation of downstream and upstream bandwidth, which can result in loss of capacity since the downstream and upstream bandwidth needs may not necessarily be static); and (ii) full duplex. Full duplex or symmetric DOCSIS 4.0, while providing significant enhancement over existing asymmetric DOCSIS systems, similarly requires significant capital investment and technology development, including relating to its supporting ecosystem (which in fact is one salient reason why the 4.0 standard also includes the first (i) mode described above, which in effect amounts to a legacy mode). The high implementation cost (including a long lead time) of continuous research and development for the newer developments in DOCSIS is moreover likely to persist, in part due to fragmented MSO selection of one of the aforementioned modes over the other.

Hence, replacing large portions of coaxial cable infrastructure with optical fiber, retrofitting to utilize the latest DOCSIS 4.0 technology, adding FWA for high-speed wireless backhaul, or other such upgrades to the existing MSO infrastructure represent (i) a huge CAPEX cost for the MSO (especially in dense urban environments with literally hundreds of closely spaced MDUs), and (ii) in some cases significant amounts of R&D for development of the necessary supporting ecosystem; these expenditures and development-induced latencies ideally would be at least partly avoided if somehow the extant HFC infrastructure could be enhanced or “repurposed” to include higher data rates, more symmetry between US and DS capability, and expanded types of services (such as mobility services).

Another issue to be addressed is the presence of delivered versus actual capacity “mismatch” with current systems. Even with delivery systems that currently provide a high degree of capability and symmetry (such as optical fiber), extant technologies for utilizing this delivered capacity symmetrically, and to its full capacity, are only now under development and not yet deployed. As such, even with a high US and DS capability available with e.g., optical fiber service, the end-user equipment such as 802.11ac routers can only utilize portions of this capability (and not nearly to its full capacity). Similarly, when considering a coaxial cable, it in theory can provide much higher data rates, and symmetrically, than current delivery paradigms such as DOCSIS 3.1 used by cable modems, and in-band 6 MHz channels (DS) used by DTSBs can provide. Hence, stated simply, the large existing inventory of coaxial cable is physically capable of much better performance than current protocols and end-user components can support.

Accordingly, improved node apparatus and methods of placement and operation thereof are needed to, inter alia, enable optimized delivery of ultra-high data rate services (both wired and wireless) symmetrically, and which leverage extant network infrastructure such as the large inventory of installed coaxial cable and supporting infrastructure in both MSO networks and the premises they serve. Such improved node apparatus and methods would also enable various network architectures that can be utilized to provide high-capacity data services to a plurality of user premises and venues under varying different configurations.

Embodiments of the present disclosure also provide related systems, methods, and/or program products.

### BRIEF SUMMARY OF THE DISCLOSURE

In accordance with one or more embodiments, a network architecture and methods involving the same are disclosed. The network architecture is configured to transmit a coexisting signal of both a Data Over Cable Services Interface Specification (DOCSIS) signal and a 5G signal, the architecture including a node apparatus that includes a Distributed Unit (DU); and a Radio Unit (RU) in communication with the DU, and the architecture includes a customer premises equipment (CPE) apparatus.

These and other advantages of the disclosure will be apparent to those of ordinary skill in the art by reference to the following detailed description and the accompanying drawings.

### BRIEF DESCRIPTION OF THE DRAWINGS

The accompanying drawings, which are incorporated in and constitute a part of this specification, illustrate embodiments of the disclosure, and, together with the summary given above, and the detailed description of the embodiments below, serve as a further explanation and disclosure to explain and/or illustrate embodiments of the disclosure. The following drawings are presented by way of example only and without limitation, wherein like reference numerals (when used) indicate corresponding elements throughout the several views, and wherein:

FIG. 1 is a block diagram of an exemplary embodiment of a system, within which one or more aspects of the invention can be implemented.

FIG. 2 is a functional block diagram illustrating a typical prior art managed (e.g., HFC cable) content delivery network architecture.

FIG. 3 is a functional block diagram illustrating a typical prior art managed (e.g., HFC cable) content delivery network architecture.

FIG. 4 is a graphical representation of an exemplary frequency band functional assignment according to an embodiment of the present disclosure.

FIG. 5 is a graphical representation of another exemplary frequency band functional assignment according to an embodiment of the present disclosure.

FIG. 6 is a graphical representation of yet another exemplary frequency band functional assignment according to an embodiment of the present disclosure.

FIG. 7 depicts a block diagram of a network architecture benefiting from the various embodiments.

FIG. 8 depicts a block diagram of a node of an embodiment of the present disclosure.

FIG. 9 depicts a block diagram of a node of an embodiment of the present disclosure.

FIG. 10 depicts a block diagram of a customer premises equipment (CPE).

FIG. 11 depicts a more detailed view of the CPE of FIG. 8.

FIG. 12 depicts a flow diagram for a method of frequency selection.

FIG. 13 depicts a block diagram of a network architecture benefiting from the various embodiments.

FIG. 14 depicts a block diagram of a small cell repeater.

FIG. 15 depicts a block diagram of a network architecture for a plurality of small cell repeaters.

All Figures® Copyright 2024 Charter Communications Operating, LLC. All rights reserved.

### DETAILED DESCRIPTION

To facilitate the understanding of this disclosure a number of terms in quotation marks are defined below. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that various embodiments of the present application may be practiced without these specific details. In other instances, well-known structures or processing steps have not been described in detail in order to avoid obscuring the present application.

The following description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for pedagogical purposes to aid the reader in understanding the principles of the invention and the concepts contributed by the inventor(s) to furthering the art, and are to be construed as being without limitation to such specifically recited examples and conditions. Additionally, the term, “or,” as used herein, refers to a non-exclusive or, unless otherwise indicated (e.g., “or else” or “or in the alternative”). Also, the various embodiments described herein are not necessarily mutually exclusive, as some embodiments can be combined with one or more other embodiments to form new embodiments.

The numerous innovative teachings of the present application will be described with particular reference to the presently preferred exemplary embodiments. However, it should be understood that this class of embodiments provides only a few examples of the many advantageous uses of the innovative teachings herein. In general, statements made in the specification of the present application do not necessarily limit any of the various claimed inventions. Moreover, some statements may apply to some inventive features but not to others. Those skilled in the art and informed by the teachings herein will realize that the invention is also applicable to various other technical areas or embodiments.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when element is referred to as being “beneath” or “under” another element, it can be directly beneath or under the other element, or intervening elements may be present. In contrast, when an element is referred to as being “directly beneath” or “directly under” another element, there are no intervening elements present.

As used herein, the term “substantially” or “substantial”, is equally applicable when used in a negative connotation to refer to the complete or near complete lack of an action, characteristic, property, state, structure, item, or result. For example, a surface that is “substantially” flat would either be completely at, or so nearly flat that the effect would be the same as if it were completely flat.

As used herein, terms defined in the singular are intended to include those terms defined in the plural and vice versa.

As used in this specification and its appended claims, terms such as “a”, “an” and “the” are not intended to refer to only a singular entity but include the general class of which a specific example may be used for illustration, unless the context dictates otherwise. The terminology herein is used to describe specific embodiments of the disclosure, but their usage does not delimit the disclosure, except as outlined in the claims.

Unless otherwise indicated, all numbers expressing quantities of ingredients, properties such as molecular weights, reaction conditions, and so forth as used in the specification and claims are to be understood as being modified in all instances by the term “about.” Accordingly, unless indicated to the contrary, the numerical parameters in the specification and claims are approximations that may vary depending upon the desired properties sought to be obtained by the present disclosure. At the very least, and without limiting the application of the doctrine of equivalents to the scope of the claims, each numerical parameter should at least be construed in light of the number of reported significant digits and by applying ordinary rounding techniques. Notwithstanding that the numerical ranges and parameters describing the broad scope of the disclosure are approximations, the numerical values in the specific examples are reported as precisely as possible. Any numerical value, however, inherently contains standard deviations that necessarily result from the errors found in the numerical value's testing measurements.

Thus, reference herein to any numerical range expressly includes each numerical value (including fractional numbers and whole numbers) encompassed by that range. To illustrate, reference herein to a range of “at least 50” or “at least about 50” includes whole numbers of 50, 51, 52, 53, 54, 55, 56, 57, 58, 59, 60, etc., and fractional numbers 50.1, 50.2 50.3, 50.4, 50.5, 50.6, 50.7, 50.8, 50.9, etc. In a further illustration, reference herein to a range of “less than 50” or “less than about 50” includes whole numbers 49, 48, 47, 46, 45, 44, 43, 42, 41, 40, etc., and fractional numbers 49.9, 49.8, 49.7, 49.6, 49.5, 49.4, 49.3, 49.2, 49.1, 49.0, etc. In yet another illustration, reference herein to a range of from “5 to 10” includes whole numbers of 5, 6, 7, 8, 9, and 10, and fractional numbers 5.1, 5.2, 5.3, 5.4, 5.5, 5.6, 5.7, 5.8, 5.9, etc.

In the discussion and claims herein, the term “about” indicates that the value listed may be somewhat altered, as long as the alteration does not result in nonconformance of the process or structure to the illustrated embodiment. For example, for some elements the term “about” can refer to a variation of +0.1%, for other elements, the term “about” can refer to a variation of +1% or +10%, or any point therein.

As used herein, the term “access node” refers generally and without limitation to a network node which enables communication between a user or client device and another entity within a network, such as for example a CBRS CBSD, a cellular xNB, a Wi-Fi AP, or a Wi-Fi-Direct enabled client or other device acting as a Group Owner (GO).

As used herein, the term “application” (or “app”) refers generally and without limitation to a unit of executable software that implements a certain functionality or theme. The themes of applications vary broadly across any number of disciplines and functions (such as on-demand content management, e-commerce transactions, brokerage transactions, home entertainment, calculator etc.), and one application may have more than one theme. The unit of executable software generally runs in a predetermined environment; for example, the unit could include a downloadable Java Xlet™ that runs within the JavaTV™ environment.

As used herein, the term “CBRS” refers without limitation to the CBRS architecture and protocols described in Signaling Protocols and Procedures for Citizens Broadband Radio Service (CBRS): Spectrum Access System (SAS)—Citizens Broadband Radio Service Device (CBSD) Interface Technical Specification—Document WINNF-TS-0016, Version V1.2.1. 3, January 2018, incorporated herein by reference in its entirety, and any related documents or subsequent versions thereof.

As used herein, the terms “client device” or “user device” or “UE” include, but are not limited to, set-top boxes (e.g., DSTBs), gateways, modems, personal computers (PCs), and minicomputers, whether desktop, laptop, or otherwise, and mobile devices such as handheld computers, PDAs, personal media devices (PMDs), tablets, “phablets”, smartphones, and vehicle infotainment systems or portions thereof.

As used herein, the term “computer program” or “software” is meant to include any sequence or human or machine cognizable steps which perform a function. Such program may be rendered in virtually any programming language or environment including, for example, C/C++, Fortran, COBOL, PASCAL, assembly language, markup languages (e.g., HTML, SGML, XML, VoXML), and the like, as well as object-oriented environments such as the Common Object Request Broker Architecture (CORBA), Java™ (including J2ME, Java Beans, etc.) and the like.

As used herein, the term “DOCSIS” refers to any of the existing or planned variants of the Data Over Cable Services Interface Specification, including for example DOCSIS versions 1.0, 1.1, 2.0, 3.0, 3.1 and 4.0 and any EuroDOCSIS counterparts or derivatives relating thereto, as well as so-called “Extended Spectrum DOCSIS”.

As used herein, the term “headend” or “backend” refers generally to a networked system controlled by an operator (e.g., an MSO) that distributes programming to MSO clientele using client devices. Such programming may include literally any information source/receiver including, inter alia, free-to-air TV channels, pay TV channels, interactive TV, over-the-top services, streaming services, and the Internet.

As used herein, the terms “Internet” and “internet” are used interchangeably to refer to inter-networks including, without limitation, the Internet. Other common examples include but are not limited to: a network of external servers, “cloud” entities (such as memory or storage not local to a device, storage generally accessible at any time via a network connection, and the like), service nodes, access points, controller devices, client devices, etc.

As used herein, the term “LTE” refers to, without limitation and as applicable, any of the variants or Releases of the Long-Term Evolution wireless communication standard, including LTE-U (Long Term Evolution in unlicensed spectrum), LTE-LAA (Long Term Evolution, Licensed Assisted Access), LTE-A (LTE Advanced), and 4G/4.5G LTE.

As used herein, the term “memory” includes any type of integrated circuit or other storage device adapted for storing digital data including, without limitation, ROM, PROM, EEPROM, DRAM, SDRAM, DDR/2 SDRAM, EDO/FPMS, RLDRAM, SRAM, “flash” memory (e.g., NAND/NOR), 3D memory, and PSRAM.

As used herein, the terms “microprocessor” and “processor” or “digital processor” are meant generally to include all types of digital processing devices including, without limitation, digital signal processors (DSPs), reduced instruction set computers (RISC), general-purpose (CISC) processors, microprocessors, gate arrays (e.g., FPGAs), PLDs, reconfigurable computer fabrics (RCFs), array processors, secure microprocessors, and application-specific integrated circuits (ASICs). Such digital processors may be contained on a single unitary IC die, or distributed across multiple components.

As used herein, the terms “MSO” or “multiple systems operator” refer to a cable, satellite, or terrestrial network provider having infrastructure required to deliver services including programming and data over those mediums.

As used herein, the terms “MNO” or “mobile network operator” refer to a cellular, satellite phone, WMAN (e.g., 802.16), or other network service provider having infrastructure required to deliver services including without limitation voice and data over those mediums.

As used herein, the terms “network” and “bearer network” refer generally to any type of telecommunications or data network including, without limitation, hybrid fiber coax (HFC) networks, satellite networks, telco networks, and data networks (including MANs, WANs, LANs, WLANs, internets, and intranets). Such networks or portions thereof may utilize any one or more different topologies (e.g., ring, bus, star, loop, etc.), transmission media (e.g., wired/RF cable, RF wireless, millimeter wave, optical, etc.) and/or communications or networking protocols (e.g., SONET, DOCSIS, IEEE Std. 802.3, ATM, X.25, Frame Relay, 3GPP, 3GPP2, LTE/LTE-A/LTEU/LTE-LAA, 5G NR, WAP, SIP, UDP, FTP, RTP/RTCP, H.323, etc.).

As used herein, the term “network interface” refers to any signal or data interface with a component or network including, without limitation, those of the Fire Wire (e.g., FW400, FW800, etc.), USB (e.g., USB 2.0, 3.0. OTG), Ethernet (e.g., 10/100, 10/100/1000 (Gigabit Ethernet), 10-Gig-E, etc.), MoCA, Coaxsys (e.g., TVnet™), radio frequency tuner (e.g., in-band or OOB, cable modem, etc.), LTE/LTE-A/LTE-U/LTE-LAA, Wi-Fi (802.11), WiMAX (802.16), Z-wave, PAN (e.g., 802.15), or power line carrier (PLC) families.

As used herein the terms “5G” and “New Radio” or “NR” refer without limitation to apparatus, methods or systems compliant with 3GPP Releases 15-19, and any modifications, subsequent Releases, or amendments or supplements thereto which are directed to New Radio technology, whether licensed or unlicensed. NG-RAN or “NextGen RAN (Radio Area Network)” is part of the 3GPP “5G” next generation radio system. 3GPP specifies its components, and interactions among the involved nodes including so-called “gNBs” (next generation Node B's or eNBs). NG-RAN will provide very high-bandwidth, very low-latency (e.g., on the order of 1 ms or less “round trip”) wireless communication and efficiently utilize, depending on application, both licensed and unlicensed spectrum of the type described supra in a wide variety of deployment scenarios, including indoor “spot” use, urban “macro” (large cell) coverage, rural coverage, use in vehicles, and “smart” grids and structures. NG-RAN will also integrate with 4G/4.5G systems and infrastructure, and moreover new LTE entities are used (e.g., an “evolved” LTE eNB or “eLTE eNB” which supports connectivity to both the EPC (Evolved Packet Core) and the NR “NGC” (Next Generation Core).

In some aspects, exemplary Release 15 NG-RAN leverages technology and functions of extant LTE/LTE-A technologies (colloquially referred to as 4G or 4.5G), as bases for further functional development and capabilities. For instance, in an LTE-based network, upon startup, an eNB (base station) establishes S1-AP connections towards the MME (mobility management entity) whose commands the eNB is expected to execute. An eNB can be responsible for multiple cells (in other words, multiple Tracking Area Codes corresponding to E-UTRAN Cell Global Identifiers). The procedure used by the eNB to establish the aforementioned S1-AP connection, together with the activation of cells that the eNB supports, is referred to as the S1 SETUP procedure; see inter alia, 3GPP TS 36.413 V14.4. entitled “3rd Generation Partnership Project; Technical Specification Group Radio Access Network; Evolved Universal Terrestrial Radio Access Network (E-UTRAN); S1 Application Protocol (S1AP) (Release 14)” dated September 2017, which is incorporated herein by reference in its entirety.

As used herein, the term “QAM” refers to modulation schemes used for sending signals over e.g., cable or other networks. Such modulation scheme might use any constellation level (e.g. QPSK, 16-QAM, 64-QAM, 256-QAM, etc.) depending on details of a network. A QAM may also refer to a physical channel modulated according to the schemes.

As used herein, the term “SAS (Spectrum Access System)” refers without limitation to one or more SAS entities which may be compliant with FCC Part 96 rules and certified for such purpose, including (i) Federal SAS (FSAS), (ii) Commercial SAS (e.g., those operated by private companies or entities), and (iii) other forms of SAS.

As used herein, the term “server” refers to any computerized component, system or entity regardless of form which is adapted to provide data, files, applications, content, or other services to one or more other devices or entities on a computer network.

As used herein, the term “storage” refers to without limitation computer hard drives, DVR device, memory, RAID devices or arrays, optical media (e.g., CD-ROMs, Laserdiscs, Blu-Ray, etc.), or any other devices or media capable of storing content or other information.

As used herein, the term “users” may include without limitation end users (e.g., individuals, whether subscribers of the MSO network, the MNO network, or other), the receiving and distribution equipment or infrastructure such as a FWA/CPE or CBSD, venue operators, third party service providers, or even entities within the MSO itself (e.g., a particular department, system or processing entity).

As used herein, the term “Wi-Fi” refers to, without limitation and as applicable, any of the variants of IEEE Std. 802.11 or related standards including 802.11 a/b/g/n/s/v/ac/ad/ax/ba or 802.11-2012/2013, 802.11-2016, as well as Wi-Fi Direct (including inter alia, the “Wi-Fi Peer-to-Peer (P2P) Specification”, incorporated herein by reference in its entirety).

As used herein, the term “wireless” means any wireless signal, data, communication, or other interface including without limitation Wi-Fi, Bluetooth/BLE, 3GPP/3GPP2, HSDPA/HSUPA, TDMA, CBRS, CDMA (e.g., IS-95A, WCDMA, etc.), FHSS, DSSS, GSM, PAN/802.15, WiMAX (802.16), 802.20, Zigbee®, Z-wave, narrowband/FDMA, OFDM, PCS/DCS, LTE/LTE-A/LTE-U/LTE-LAA, 5G NR, LoRa, IoT-NB, SigFox, analog cellular, CDPD, satellite systems, millimeter wave or microwave systems, acoustic, and infrared (i.e., IrDA). As used herein, the term “xNB” refers to any 3GPP-compliant node including without limitation eNBs (cUTRAN) and gNBs (5G NR).

In one exemplary aspect, the present disclosure provides improved network architectures, and node apparatus and associated methods for providing enhanced ultra-high data rate services which, inter alia, leverage existing managed network (e.g., cable network/HFC) infrastructure. Advantageously, the disclosed architectural components (nodes, amplifiers, cores, taps and counterpart CPE) can be utilized in a variety of topologies, with network nodes disposed so as to support multiple downstream CPE including e.g., wherever an optical waveform is to be converted to a signal to be transmitted via coaxial cable. For instance, in one configuration, a node may be used further back towards the service provider core, such as to support a number of individual customer premises (e.g., homes) served by coaxial cable infrastructure. In another configuration, the node may be used at the very edge of the network to service a number of customers within a residential multi-dwelling unit or MDU (e.g., apartment building or condominium complex), that is wired with coaxial cable yet served by a proximate fiber drop (e.g., FTTC).

Further, other exemplary configurations can support various types of use cases (including premises-specific ones) such as e.g., providing an outdoor small cell service, a distributed antenna system (DAS) for an enterprise or other such premises, a venue-specific DAS, and additional reliability through redundancy. Numerous other configurations are possible when utilizing the adaptable and application-specific configurability of the methods and apparatus described herein.

In one embodiment of the architecture, a Hybrid Fiber Coax (HFC) plant infrastructure and/or 802.11ax (colloquially termed “Wi-Fi 6”) protocols are used as bases for provision of standards-compliant ultra-low latency and high data rate services (e.g., with capabilities associated with 3GPP 4G and 5G, and IEEE Std. 802.11 services based on 802.11ax technology). These services may include symmetric or asymmetric US and DS bandwidth which can be dynamically allocated, flexible scheduling of data (to e.g., prioritize real-time data over non-real-time data), and support of cellular, WLAN and PAN (e.g., IoT) services, all via a common service provider. The exemplary use of Wi-Fi 6 technology provides not only the capability for symmetric operation of downstream (DS) and upstream (US) transmissions but also a symmetric capacity, which may not be possible with e.g., use of an 802.11ac router backhauled by DOCSIS.

Further, various configurations and topologies, made available via the aforementioned technologies and the HFC plant infrastructure, are used for provision of various types standards-compliant ultra-low latency and high data rate services to user devices disposed at edge of a distribution network, as well as within different types of venues.

In one variant, an expanded frequency band (approximately 1.6-4 GHZ in total bandwidth) is used over the coaxial portions of the HFC infrastructure. This expanded band is allocated to two or more primary data sub-bands, as well as to Industrial, Scientific and Medical (ISM) and cellular uses. Wideband amplifier apparatus are used to support DS and US utilization of the sub-bands within the network, including by premises devices via re-use of coaxial infrastructure. This allows the entity that installed such coaxial infrastructure to maintain its footprint in its customer's premises and continue to provide additional services without laying any significant amounts of optical fiber or other such alternate solutions.

In another variant, the foregoing expanded frequency band is divided among and used by two (or more) sub-nodes to provide data services that are better suited to different types of user premises or use cases. Additionally, the division of the expanded frequency band allows the sub-nodes to carry less capabilities/components so as to allow e.g., lower per-unit cost.

In yet another variant, the use of 802.11ax APs for delivery of ultra-high data rate services allow e.g., 4.8 Gbps data rate services, which can allow for example two (2) users to take advantage of 2.4 Gbps data rate in parallel (instead of allowing one (1) user to get all of 4.8 Gbps due to silicon limitation). In another variant, a plurality of access and modulation scheme, such as an OFDM and TDD/FDD/LBT-based scheme is used to allow for maximal efficiency and flexibility in allocating bandwidth to downstream and upstream transmissions over the HFC infrastructure.

Moreover, latency within the disclosed infrastructure is reduced by, inter alia, obviating encapsulation and other network/transport protocols normally necessitated through use of e.g., DOCSIS bearers and equipment (i.e., DOCSIS modems and cable-modem termination system (CMTS) apparatus within the MSO core).

### DETAILED DESCRIPTION OF EXEMPLARY EMBODIMENTS

Exemplary embodiments of the apparatus and methods of the present disclosure are now described in detail. While these exemplary embodiments are described in the context of the previously mentioned HFC cable system adapted for use with 5G and 3GPP technology, and network nodes, taps and CPE associated with or supported at least in part by a managed network of a service provider (e.g., MSO), other types of radio access technologies (“RATs”), and other types of networks and architectures that are configured to deliver digital data (e.g., text, images, games, software applications, video and/or audio) may be used consistent with the present disclosure. Such other networks or architectures may be broadband, narrowband, or otherwise, the following therefore being merely exemplary in nature.

It will also be appreciated that while described generally in the context of a network providing service to a customer or consumer or end user or subscriber (i.e., within a prescribed service area, venue, or other type of premises), the present disclosure may be readily adapted to other types of environments including, e.g., commercial/retail, or enterprise domain (e.g., businesses), or even governmental uses.

Additionally, while described primarily with reference to exemplary architectures and components set forth in co-owned U.S. Pat. No. 11,843,474 filed Feb. 11, 2020 and entitled “APPARATUS AND METHODS FOR PROVIDING HIGH-CAPACITY DATA SERVICES OVER A CONTENT DELIVERY NETWORK,” incorporated herein by reference in its entirety, the methods and apparatus of the present disclosure are not so limited, and in fact may adapted for use with other architectures and components by one of ordinary skill when given the present disclosure.

Also, while certain aspects are described primarily in the context of the well-known Internet Protocol (described in, inter alia, Internet Protocol DARPA Internet Program Protocol Specification, IETF RCF 791 (September 1981) and Deering et al., Internet Protocol, Version 6 (IPv6) Specification, IETF RFC 2460 (December 1998), each of which is incorporated herein by reference in its entirety), it will be appreciated that the present disclosure may utilize other types of protocols (and in fact bearer networks to include other internets and intranets) to implement the described functionality.

Other features and advantages of the present disclosure will immediately be recognized by persons of ordinary skill in the art with reference to the attached drawings and detailed description of exemplary embodiments as given below.

### Exemplary Network Architecture

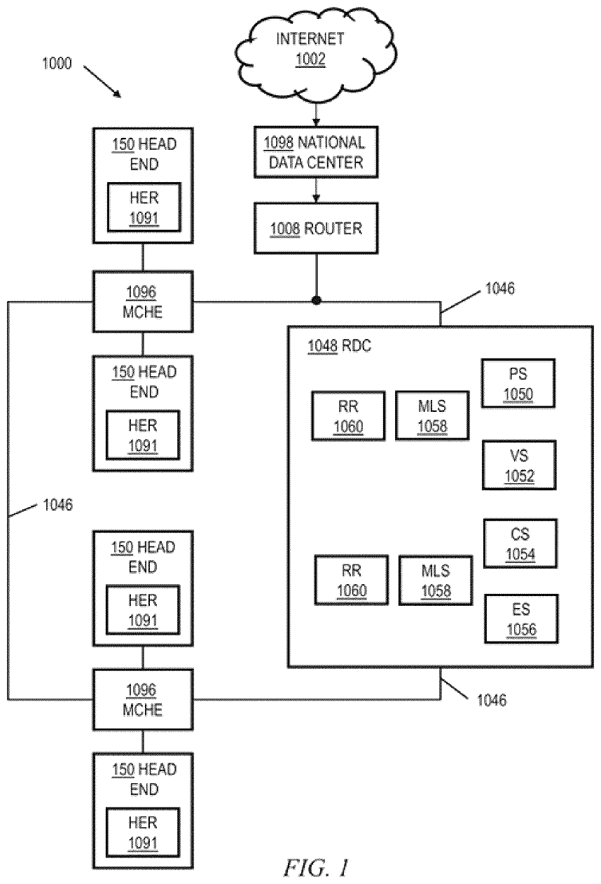

By way of example and not limitation, some embodiments will be shown in the context of a cable multi-service operator (MSO) providing data services as well as entertainment services. FIG. 1 shows an exemplary system 1000, according to an aspect of the invention. System 1000 includes a regional data center (RDC) 1048 coupled to several Market Center Head Ends (MCHEs) 1096; each MCHE 1096 is in turn coupled to one or more divisions, represented by division head ends 150. In a non-limiting example, the MCHEs are coupled to the RDC 1048 via a network of switches and routers. One suitable example of network 1046 is a dense wavelength division multiplex (DWDM) network. The MCHEs can be employed, for example, for large metropolitan area(s). In addition, the MCHE is connected to localized HEs 150 via high-speed routers 1091 (“HER”=head end router) and a suitable network, which could, for example, also utilize DWDM technology. Elements 1048, 1096 on network 1046 may be operated, for example, by or on behalf of a cable MSO, and may be interconnected with a global system of interconnected computer networks that use the standardized Internet Protocol Suite (TCP/IP) (transfer control protocol/Internet protocol), commonly called the Internet 1002; for example, via router 1008. In one or more non-limiting exemplary embodiments, router 1008 is a point-of-presence (“POP”) router; for example, of the kind available from Juniper Networks, Inc., Sunnyvale, California, USA.

Head end routers 1091 are omitted from figures below to avoid clutter, and not all switches, routers, etc. associated with network 1046 are shown, also to avoid clutter. RDC 1048 may include one or more provisioning servers (PS) 1050, one or more Video Servers (VS) 1052, one or more content servers (CS) 1054, and one or more e-mail servers (ES) 1056. The same may be interconnected to one or more RDC routers (RR) 1060 by one or more multi-layer switches (MLS) 1058. RDC routers 1060 interconnect with network 1046.

A national data center (NDC) 1098 is provided in some instances; for example, between router 1008 and Internet 1002. In one or more embodiments, such an NDC may consolidate at least some functionality from head ends (local and/or market center) and/or regional data centers. For example, such an NDC might include one or more VOD servers; switched digital video (SDV) functionality; gateways to obtain content (e.g., program content) from various sources including cable feeds and/or satellite; and so on.

In some cases, there may be more than one national data center 1098 (e.g., two) to provide redundancy. There can be multiple regional data centers 1048. In some cases, MCHEs could be omitted and the local head ends 150 coupled directly to the RDC 1048.

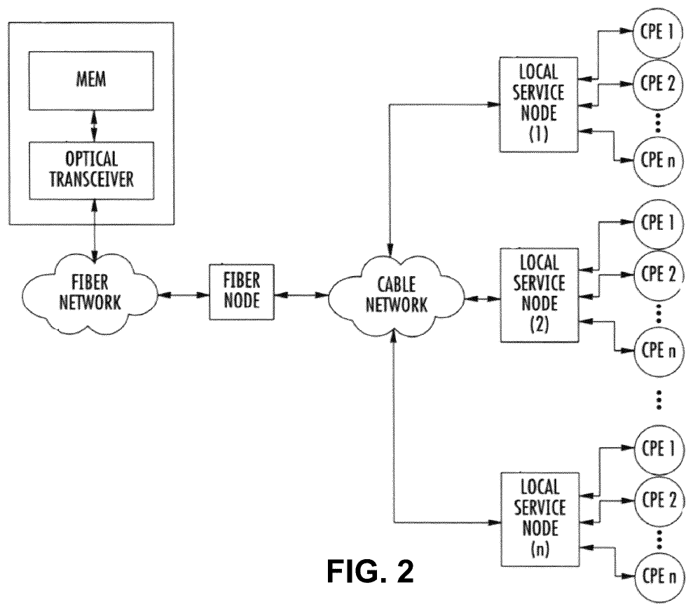

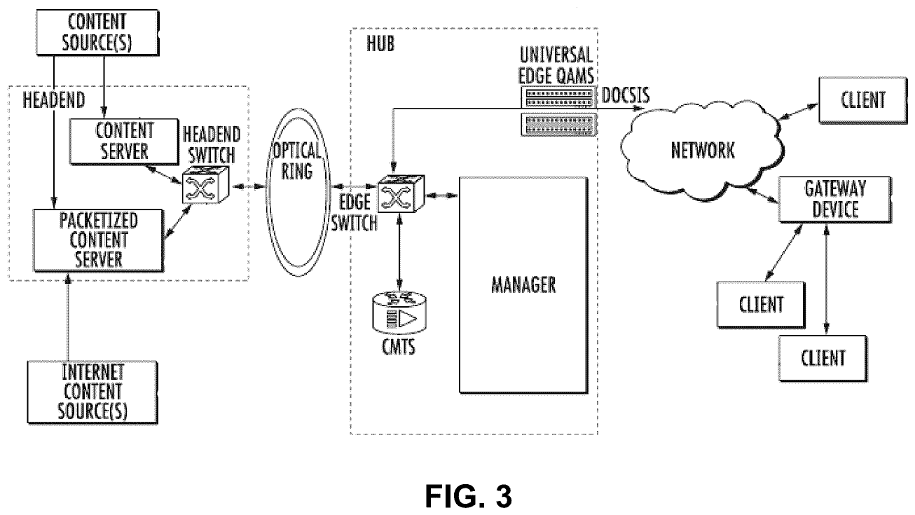

Under existing paradigms, network operators deliver data services (e.g., broadband) and video products to customers using a variety of different devices, thereby enabling their users or subscribers to access data/content in a number of different contexts, both fixed (e.g., at their residence) and mobile (such as while traveling or away from home). FIG. 2 and FIG. 3 are functional block diagrams illustrating a typical prior art managed (e.g., HFC) content delivery network architecture used to provide such data services.

In such networks, data/content delivery may be specific to the network operator, such as where content is ingested by the network operator or its proxy, and delivered to the network users or subscribers as a product or service of the network operator. For instance, a cable multiple systems operator (MSO) may ingest content from multiple different sources as shown in FIG. 1 (e.g., national networks, content aggregators, etc.), process the ingested content, and deliver it to the MSO subscribers via their hybrid fiber coax (HFC) cable/fiber network, such as to the subscriber's set-top box or DOCSIS cable modem.

Within the cable plant, VOD and so-called switched digital video (SDV) may also be used to provide content, and via utilization of a single-program transport stream (SPTS) delivery modality. In U.S. cable systems for example, downstream RF channels used for transmission of television programs are 6 MHz wide, and occupy a multitude of 6-MHz spectral slots between 54 MHz and 860 MHz. Upstream and “out of band” communications are normally relegated to the lower end of the available spectrum, such as between 5 and 85 MHz. Deployments of VOD services have to share this spectrum with already established analog and digital services such as those described herein. Within a given cable plant, all homes that are electrically connected to the same cable feed running through a neighborhood will receive the same downstream signal. For the purpose of managing e.g., VOD services, these homes are grouped into logical groups typically called Service Groups. Homes belonging to the same Service Group receive their VOD service on the same set of RF channels.

Existing cable systems utilize what in effect amounts to a Frequency-Division Multiplexing (FDM) system with 6 MHz channels and roughly 700 MHz of available bandwidth capacity in total, each of the channels being QAM modulated and delivered to the end user via e.g., a tree-and-branch type of topology, with user's CPE (e.g., digital settop boxes, DOCSIS modems, and gateways) utilizing RF tuners to tune to the appropriate DS channels to receive their respective data or program streams. As previously noted, this approach has limitations on its capacity, and hence can only be expanded so far in terms of available bandwidth (both DS and US) and serving additional customers with additional services.

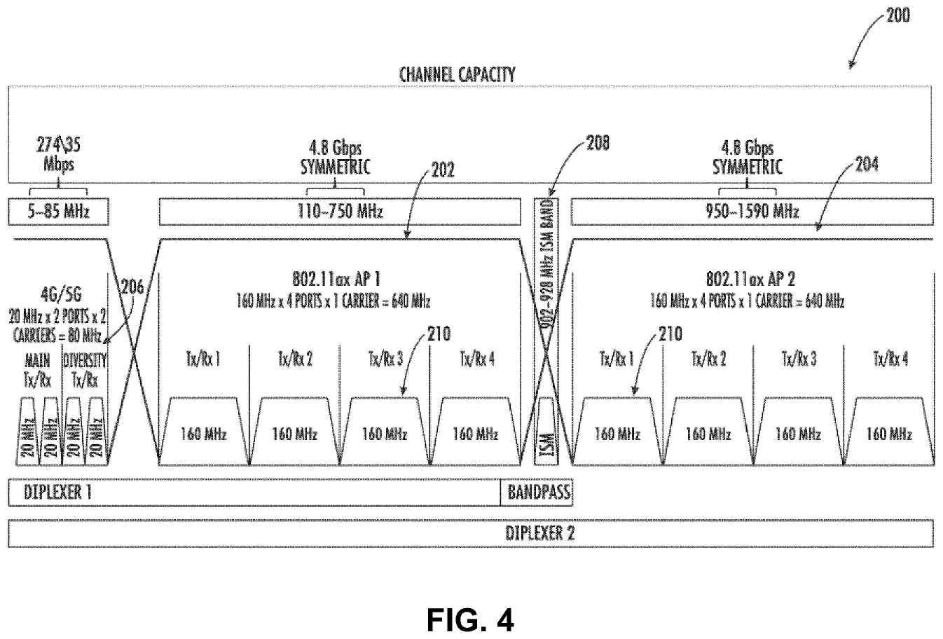

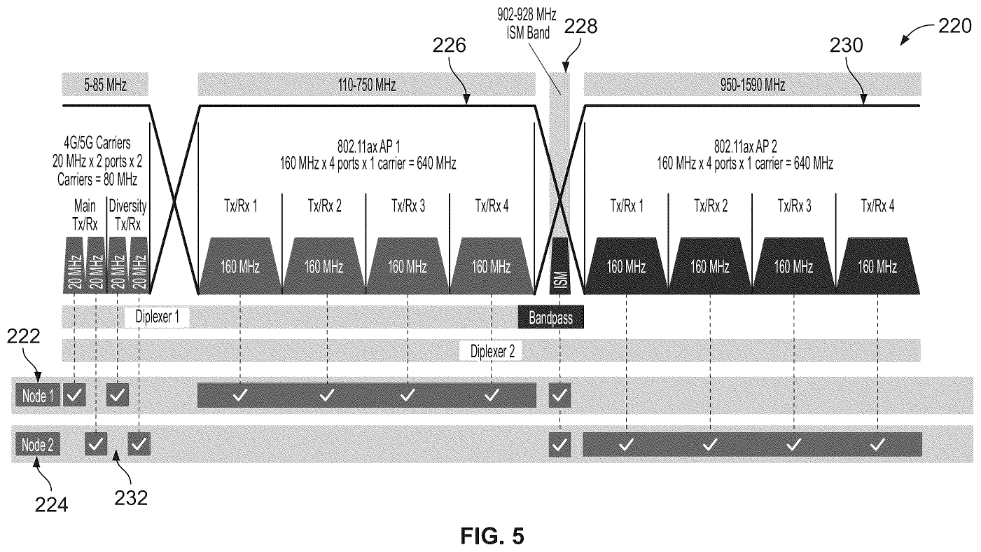

Accordingly, a new model is needed. As shown in the exemplary frequency plan 200 of FIG. 4, various embodiments of the present disclosure utilize two bands 202, 204 each comprised of four (4) 160-MHz-wide channels 210, the two bands as supported by each of two (2) 802.11ax-based APs (see discussion of FIGS. 4-5 infra), can each provide a symmetric data service at the rate of 4.8 Gbps. Due to extant silicon limitations in current 802.11ax chipsets as of the date of this disclosure, the entirety of the 4.8 Gbps bandwidth cannot be allocate to a single user; however, such capability is incipient, and the present disclosure explicitly contemplates such configurations. However, even under the existing silicon, two (2) users can each utilize up to 2.4 Gbps in parallel. Therefore, the two (2) 802.11ax APs can provide a very high data rate service by utilizing the two sets of four (4) 160-MHz channels.

Moreover, the frequency use plan 200 of FIG. 4 includes provision for other functions (in addition to symmetric or asymmetric primary band uses), including support of cellular waveforms provided via 5-85 MHz band 206 (which as noted previously is generally used for upstream data communication for DOCSIS or OOB communication in traditional cable systems), as well as data communication via one or more ISM bands 208 (e.g., at 902-928 MHz).

As will be described in greater detail below, the cellular band(s) 206 can support transmission of e.g., 3GPP 4G/4.5G/5G waveforms, over HFC, to and from the customer's premises, in effect making the MSO's system a huge DAS (distributed antenna system) for a cellular operator or MNO, or even the MSO itself when acting as a wireless service provider. For instance, in one such model, the MSO may use 3GPP-based technology as an underpinning for providing unlicensed or quasi-licensed service via e.g., NR-U bands, CBRS bands, C-Band, or even mmWave bands to its users or subscribers.

Similarly, the ISM band(s) 210 within the frequency plan 200 provide a number of different functions to aid in, among other things, CPE control and fault detection by the MSO.

As shown in FIG. 4, the overall spectrum utilized by the plan 200 is on the order of 1.6 GHz, roughly twice that of a typical MSO cable band under the prior art. Notably, the portions of the extant HFC architecture leveraged as part of the architectures of the present disclosure are not inherently limited by their medium and architecture (i.e., optical fiber transport ring, with coaxial cable toward the edges); coaxial cable can operate at frequencies significantly higher than the sub-1 GHz typically used in cable systems, and such additional bandwidth is made use of in the exemplary embodiments described herein.

Further, the foregoing spectrum of e.g., 1.6 GHz in bandwidth can be divided between multiple (e.g., two (2)) sub-nodes to allow, inter alia, a spectrum use plan that can be advantageous in providing data services that are more tailored to user premises and/or applications being served. For example, as shown in the embodiment of FIG. 2A, the plan 220 allocates approximately 700 MHz of bandwidth to one sub-node (Node 1) 222 while allocating another approximately 700 MHz of bandwidth to another sub-node (Node 2) 224. The division can be used for a multitude of purposes, including e.g., providing high-capacity data services to different parts of one or more user premises, via two or more nodes providing different paths (including combining or alternating such paths to provide e.g., additional reliability through redundancy), as discussed in more detail elsewhere herein.

As can be seen in FIG. 5, one sub-node 222 can be allocated e.g., 640 MHz of bandwidth 226 that can be serviced by one (1) 802.11ax AP, while another sub-node 224 can be allocated another 640 MHz of bandwidth 230.

As discussed further herein, each node can generate and/or provide its own data to be transmitted via ISM band 228, which is a shared-use channel. Accordingly, each sub-node 222, 224 can utilize the ISM band 228 as shown in FIG. 5, to e.g., send control data. Furthermore, the cellular band(s) 232, as introduced with respect to FIG. 4 above, can also be divided between the two sub-nodes 222, 224 as needed by e.g., utilizing one or more carrier signals or bands for each sub-node 222, 224 (e.g., in 20 MHz wide slices) as shown in FIG. 5.

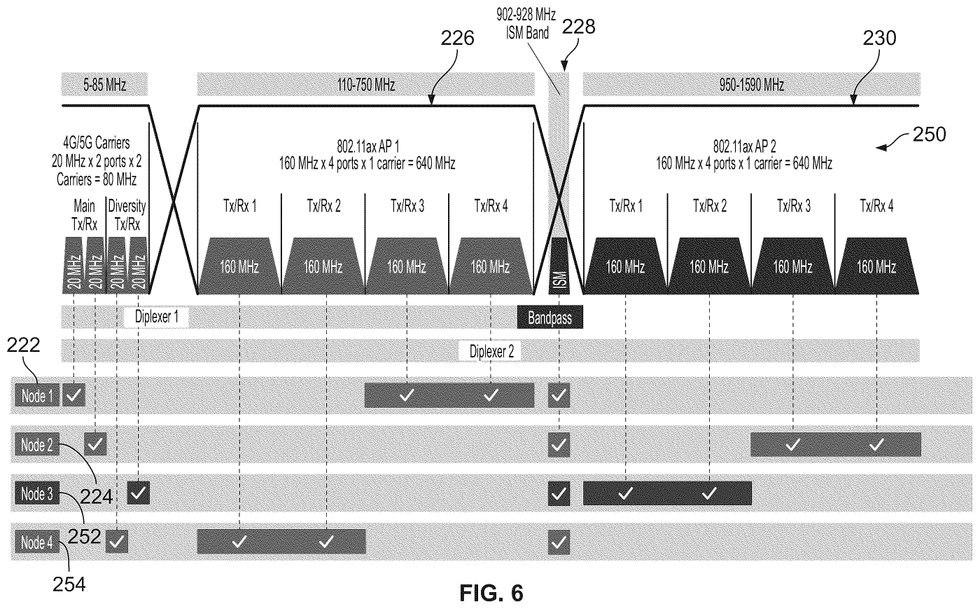

FIG. 6 illustrates yet another embodiment of a frequency plan 250 according to the present disclosure. In this plan, there are four (4) nodes 222, 224, 252, 254 which are each allocated a cellular band, two sub-band portions (of the four total comprising the bandwidth 226, 230), and use a common ISM band 228.

It will also be appreciated that the attenuation associated with any coaxial cable infrastructure is a function of, inter alia, coaxial conductor length, and hence higher levels of “per-MHz” attenuation may be acceptable for shorter runs of cable. Stated differently, nodes servicing (or serviced by) shorter runs of cable may be able to better utilize the higher-end portions of the RF spectrum (e.g., on the high end of the aforementioned exemplary 1.6 GHZ band) as compared to those more distant, the latter requiring greater or disproportionate amplification. As such, the present disclosure also contemplates embodiments which make use of selective mapping of frequency spectrum usage as a function of total cable medium run length or similar.

### Exemplary Network Architecture (700)

Generally speaking, the various embodiments find utility within the context of any bandwidth distributing/sharing device requiring a BWP assignment from a network node (e.g., base station, eNB/gNB) connected thereto, such as the local CPE described herein, where the device capability does not necessarily reflect the actual bandwidth consumption of the device itself or other devices/services supported by the device. The various embodiments described herein provide a BWP update process that is triggered for each CPE associated with a network node (e.g., base station, eNB/gNB) such that each CPE is generally allocated bandwidth as needed for a current mix of, illustratively, wireless access point (WAP) connected access terminals (ATs) and the liked so that, illustratively, a total spectrum allocated to a CBSD network node may be used as efficiently as possible.

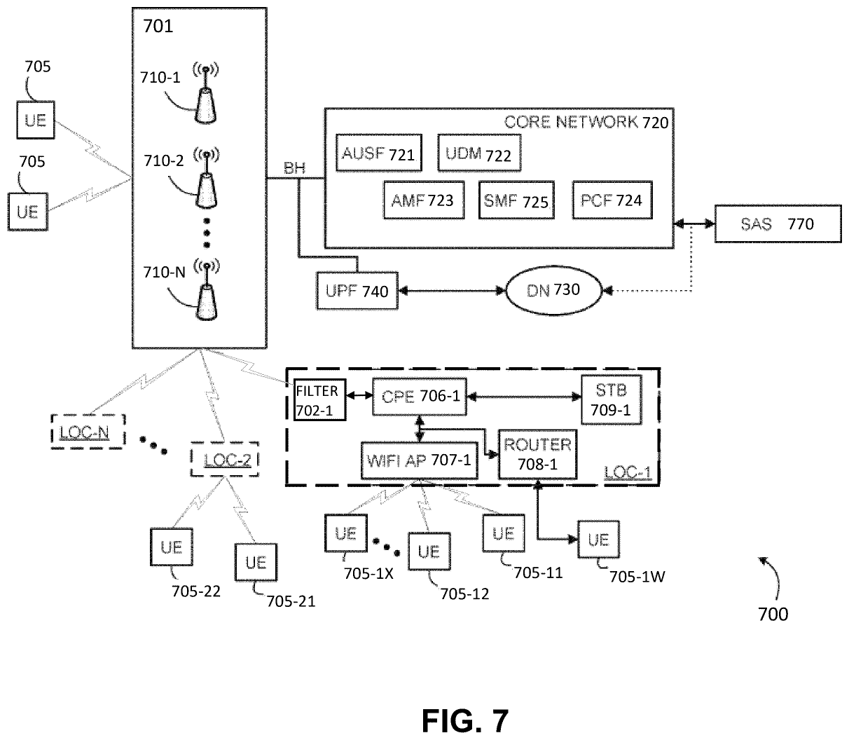

FIG. 7 depicts a block diagram of a network architecture benefiting from the various embodiments. The network architecture 700 of FIG. 7 is depicted as, illustratively, a fixed wireless access (FWA) network 700 in which a plurality of 5G network nodes 110 (eNBs, gNBs) forming a mobile network 701 are optionally configured to communicate with, and provide backhaul services to, user equipment (UE) 705, customer premises equipment (CPE) 706 functioning as UE with respect to the mobile network 701, and/or other devices. CPE 706 may support respective local WiFi access points (WIFI AP or WAPs) 707 and the traffic associated with respective Wifi devices connected thereto, including diverse sets of traffic types such as having different throughput and/or latency requirements.

As depicted in FIG. 7, service-based architecture of a 5G core network 720 is depicted in a simplified form as comprising a number of core network nodes or network functions (NFs) such as described in relevant standards documents such as the 3GPP standards for 5G (e.g. 3GPP 23.501 and 23.502), including an authentication server function (AUSF) 721, a unified data management (UDM) 722 (having a unified data repository or UDR), an Access and Mobility Function (AMF) 723, a policy control function (PCF) 724, and a service management function (SMF) 725. A plurality of interfaces or reference points NI through N15 define the communications and/or protocols between each of the entities, as described in the relevant (evolving) standards documents. One or more application functions (AFs) may connect to the 5G mobile network via PCF 724. One or more data networks (DN) 730 having application servers (AS) may be connected to the 5G mobile network through UPFs such as UPF 740. The depicted core network 720 of the 5G mobile network of FIG. 7 may also include various other network node functions (not shown for simplicity) along with their relevant interfaces.

As depicted in FIG. 7, UE 705 is configured for a wireless and/or wired communication with the mobile network 701 and CPE 706 is configured for a wired, coaxial communication with the mobile network 701 (e.g., a 5G radio access network), illustratively comprising a plurality of base stations, gNBs, or eNBs depicted herein as network nodes 710-1 through 710-N, which are connected to the combination DOCSIS/5G core network 720 via back haul (BH) and/or other communications links, with the core network 720 transmitting a signal coexisting signal of both a DOCSIS signal and a 5G signal. The DOCSIS/5G core network 720, as well as all components of the architecture, is configured to receive and transmit both 5G and DOCSIS waveforms.

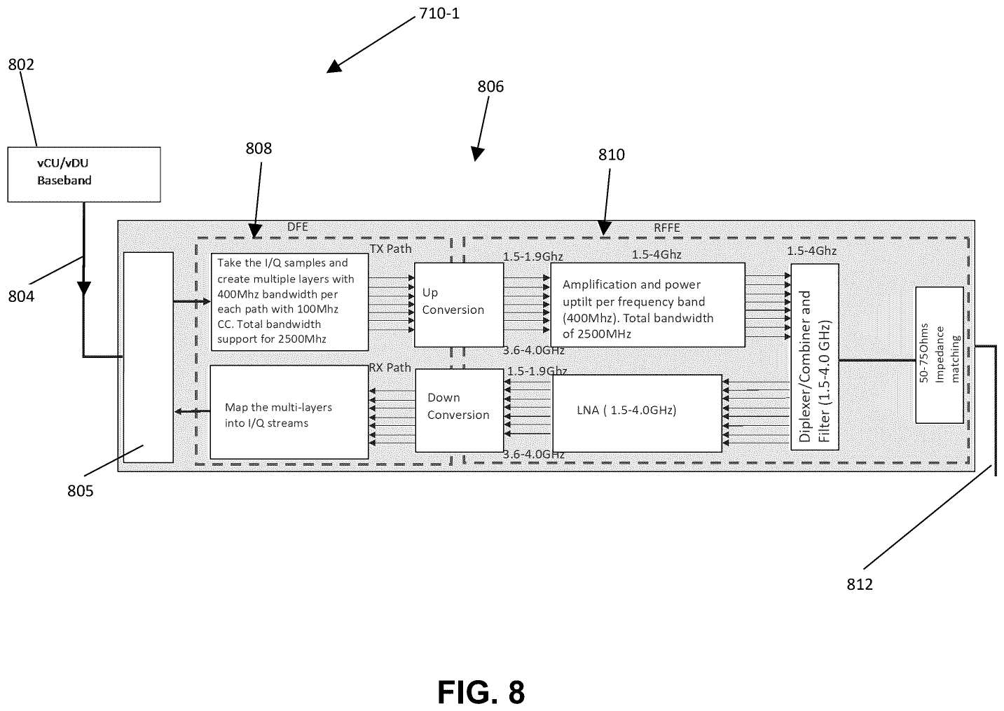

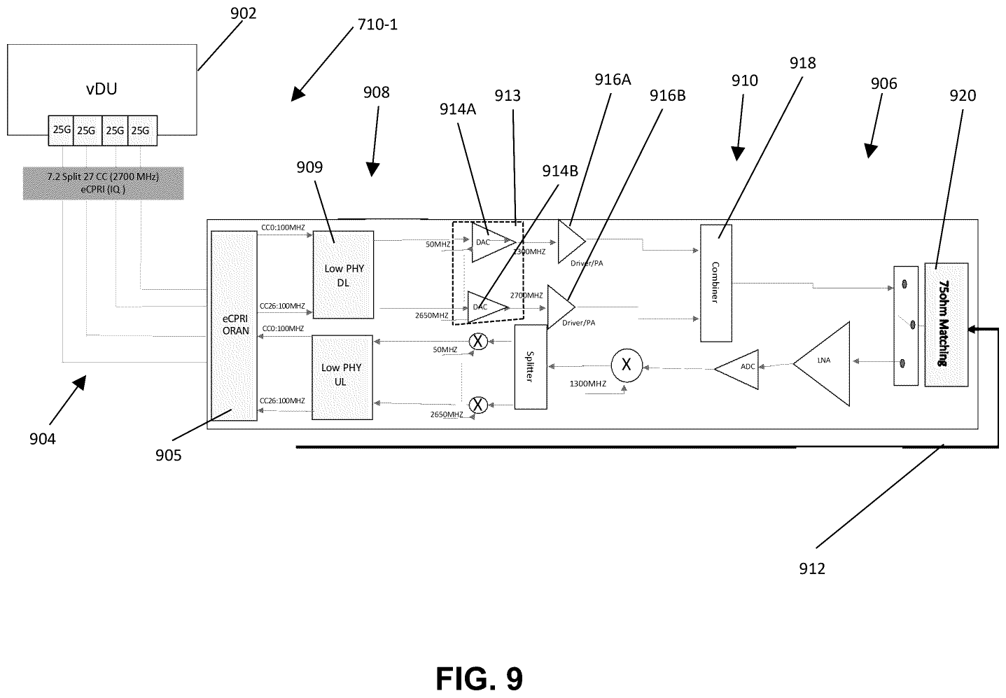

Nodes 710-1 to 710-N are described herein, and specifically described with reference to FIGS. 8 and 9, discussed below. The gNB may be formed as logical nodes or groupings of resources at a radio access network (R) AN or RAN such as implemented at network nodes 710 within the mobile network 701. The gNB formed thereat may be configured with more or fewer RAN resources so at to have features and/or capabilities selected in response to the type and number of UE and CPE connected thereto, the type of services being provided thereby, and so on. The network 701 can include a PHY functional split as espoused by the O-RAN Alliance, the PHY functions may be split between the RU (Radio Unit) of the network nodes 710 and the distributed or digital unit (DU). Protocol layers above the PHY (e.g., MAC, RLC, PDCP, SDAP) may be located at the central unit (CU). The RU-DU transport link of the network nodes 710 is known as fronthaul and CU-DU transport link is known as mid-haul. CPRI and/or eCPRI can be used as the mid-haul and fronthaul transport protocol. A further description of the midhaul and fronthaul herein and below.

UE 705 and CPE 706 provide capability information, category information, feature set information, feature set combination information and so on in accordance with various relevant protocols to indicate radio access capability parameters such as UE/CPE downlink (DL), uplink (UL) capability, and sidelink (SL) capability (i.e., maximum data rate, buffer size, and the like), transport block size, supported layers, supported modulation schemes, supported frequencies, and other features/capabilities. In response to this feature/capability information, a BWP may be assigned to the UE or CPE.

For example, a UE capability exchange or capability transfer may include the transfer of UE radio access capability information from a UE to the network. A network node such as a base station, eNB, gNB, router, access network node, core network node and the like may need to know the UE's capabilities in order to more effectively use the radio capabilities and/or other capabilities of the UE and the network with respect to different features, such as supported frequency bands or combinations thereof, DL/UL bandwidth class, multiple-input multiple-output (MIMO) antenna technology capability, dual Connectivity support, simultaneous RxTx, supported CSI-RS processes, and so on (there are numerous UE capability information elements that may be used within the context of the 5G communications standards and other standards documents).

The network node may use the UE capability information during configurations of data radio bearer (DRB), MAC, PHY, and the like. A network node may transmit a UECapabilityEnquiry to the UE, requesting the UE to respond with UE radio access capability information. The UE responds with a UECapabilityinformation message. The network node may use the capability information received to set up the MAC and PHY configuration (receive and transmit capabilities, e.g., single/dual radio, dual receiver) of the RRC connection. This exchange may also enable efficient measurement control.

Each UE 705 directly communicating with a network node 710 is assigned a bandwidth part (BWP) by its respective network node 710 in accordance with the capability of the UE 705. Similarly, each CPE 706 communicating with a network node 710 is assigned a BWP by its respective network node 710 in accordance with the capability of the CPE. Within the context of the various embodiments, the CPE 706 and UE 705 function substantially similarly to each other with respect to the mobile network 701 in terms of control plane and data plane signaling/operations, though the CPE 706 may have significantly more capability and/or bandwidth requirements than a single UE 705.

For example, a UE 705 directly communicating with a network node 710 may provide single UE capability information having fields of ‘Supported DL Throughput=100 Mbps’, ‘Supported UL Throughput=50 Mbps’ and the like, wherein the BWP assigned/allocated to this UE will be sized accordingly.

Similarly, a CPE 706 directly communicating with a network node 710 through a wired, coaxial connection and supporting a WAP 707 serving two such UEs operating as ATs thereto, may provide single UE capability information having fields of ‘Supported DL Throughput=200 Mbps’, ‘Supported UL Throughput=100 Mbps’ and the like, wherein the BWP assigned/allocated to this CPE will be sized accordingly. The CPE 706 is providing, in effect, an aggregated capability message to reflect the total bandwidth requirements (and other requirements) of the CPE in supporting the two UE in this example.

Alternatively, rather than a CPE 706 directly communicating with a network node 710, a filter 702-1 can be present between the CPE 706 and the network node 710. Filter 702-1 can be configured to be a passband filter and can be configured to support a relatively wide bandwidth, for example, about 1.5 GHz to about 4 GHz, or even higher than about 4 GHz if desired. The attenuation of the undesired signal received by the filter 702-1 can be around 85 dB (or greater by about 10%-about 20% or more, or lesser by about 10%-about 20% or more). The filter 702-1 can reduce and/or remove distortion in DOCSIS waveforms received by the filter 702-1.

Referring to FIG. 7, various embodiments dynamically adapt the size of, for example, CPE-assigned BWPs in response to changes in bandwidth requirements experienced by the CPE, such as due to changes in a number of wireless devices, such as user equipment (UE) operating as Access Terminals (ATs), attached to wireless access points (WAPs) supported by the CPE, set top boxes (STBs) supported by the CPE, and/or other wireless or wired devices connected to or receiving bandwidth consuming services via the CPE.

At least some of the UE 705 may also function as WiFi Access Terminals (ATs) for wirelessly communicating with wireless access points (WAPs) 707 deployed at various of locations LOC and supported thereat by customer premises equipment (CPE) 706 configured for wirelessly communicating with the mobile network 701.

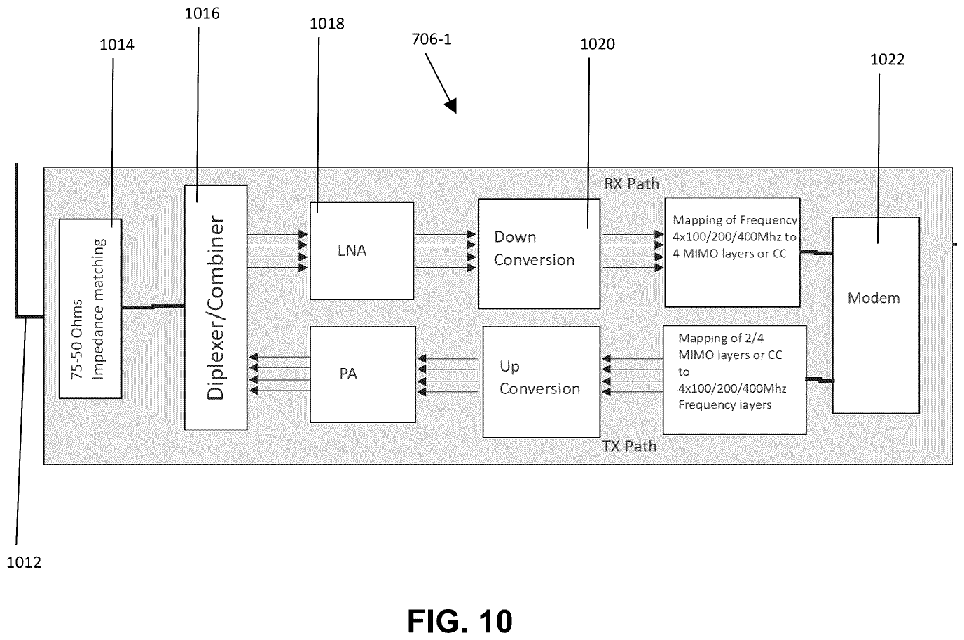

For example, a first location LOC-1 is depicted as including CPE 706-1 configured to support a WAP 707-1, a router 708-1, and a set top box (STB) 709-1. CPE 706-1 is described herein, and specifically described with reference to FIGS. 10-12, discussed below. The WAP 707-1 is depicted as communicating with a plurality of wireless devices, namely, UE 705-11 through 705-1X. The router 708-1 is depicted as communicating with wired UE 705-1 W. The STB 709-1 may be a standard cable television STB configured to deliver broadcast, video on-demand (VOD), and/or other media related services. Further, the STB 709-1 may include a local digital video recorder (DVR) configured to periodically core programming from various channels accessible to the STB 709 such as in accordance with the service level agreement (SLA) of the subscriber associated with the location LOC-1.

The network nodes 710 may comprise macrocells, small cells, microcells and the like such as eNodeBs (eNBs), cellular network base stations, repeaters, and similar types of provider equipment or logical radio nodes (e.g., gNBs) derived therefrom. The network nodes 710 and various RAN resources may comprise resources using licensed spectrum, unlicensed spectrum such as citizens broadband radio service (CBRS) spectrum, or a combination of licensed and unlicensed spectrum. The network nodes 710 may, in various embodiments, include mid-band (e.g., 3.5 GHZ) gNBs, low-band (e.g., under 1 GHZ) gNBs, or a combination of mid-band and low-band gNBs.

In the case of network nodes 710 having Citizens Broadband Radio Service Device (CBSD) capability, allocations of CBRS spectrum are provided via a Spectrum Access System (SAS) 770. Generally speaking, the SAS 770 communicates with the 5G core network 720 (optionally with the DN 730) and is configured to control access to the CBRS frequency band for CBSD network nodes 710, UE 705, CBE 706 and other CBSD devices. Generally speaking, the SAS 770 is configured to ensure that the CBRS frequency band is allocated for CBSD use, and that such use is adapted government requirements, network congestion, network interference and the like.

The WAPs 707 may comprise 802.11xx (e.g., 802.11b, 802.11a, 802.11 g, 802.11n, 802.11ac, 802.11ax and so on) wireless access points at homes, businesses, or other location that are configured to communicate with supporting CPE 706. In various embodiments, a network services provider utilizes numerous such access points distributed over a “coverage footprint” to provide network services to mobile devices such as the UE 705 discussed herein. In various embodiments, each WAP 707 maintains a list of the ATs connected thereto, the list being provided to the CED 706 as needed in accordance with the embodiments described herein.

Each network node 710 provides network services to UE 705 and CPE 706 via respective radio bearer (channels/resources) which are managed by various Radio Resource Management functions, such as Radio Bearer Control, Radio Admission Control, Connection Mobility Control, Scheduling of UE/CPE in both uplink and downlink, assignment of bandwidth parts (BWPs) to UE/CPE and so on. The Radio Resource Management functions are configured to provide appropriate Quality of Service (QoS) levels to the UE/CPE using one or more radio bearers, such as to maximize throughput at the network node 710 while maintaining “fairness” to the UE/CPE attached thereto, to monitor various performance metrics, to provide data to the core network or network management entities and the like.

Generally speaking, each of the CBSD network nodes 710 and non-CBSD network nodes 710 utilizes defined frequency ranges (FRs), such as FR1 (410 MHz to 7125 MHz), FR2 (24.25 GHz to 52.6 GHZ), and so on. These frequency ranges may include both licensed and unlicensed spectrum as discussed elsewhere herein, where unlicensed spectrum includes CBRS spectral regions used by CBSD network nodes 110. Each of the spectral regions includes a plurality of operating bands, wherein each operating band is a frequency band associated with a certain set of radio frequency (RF) requirements. Bandwidths of different operating bands can vary from several MHz to a few GHz. Further, 5G NR supports a range of channel bandwidths from 5-400 MHz, where a channel bandwidth refers to the bandwidth of an NR carrier. The number of resource blocks (RBs) that may be configured in a channel bandwidth, known as transmission bandwidth configuration, meets specified minimum guard band requirements. In various embodiments, a new radio (NR) RB is used, wherein the NR RB contains 12 sub-carriers in a resource block bandwidth fixed to 180 KHz, however resource block bandwidths larger or smaller than 180 KHz may be used in the various embodiments, such as may depend on sub-carrier spacing and the like.

Different types of UE 705 and/or CPE 706 may be able to support different channel bandwidths, and so different types of UE 1705 and CPE 706 may be assigned bandwidth parts (BWPs) of differing size, where each BWP comprises a set of contiguous RBs configured inside a channel bandwidth, typically ranging from 1 RB to 275 RBs. For example, CPE 706, as further discussed below, is configured for a very wideband bandwidth and configured to receive both 5G and DOCSIS waveforms.

As noted in 3GPP TS 38.211, “NR; Physical channels and modulation,” NR defines scalable orthogonal frequency division multiplexing (OFDM) numerologies using subcarrier spacing (SCS) of 2μ·15 kHz (μ=0, 1, . . . , 4). An RB consists of 12 consecutive subcarriers in the frequency domain. Each BWP starts at a certain common RB and consists of a set of contiguous RBs with a given numerology (SCS and cyclic prefix) on a given carrier. For each serving cell of a UE, the network configures at least one downlink (DL) BWP (i.e., the initial DL BWP). The network may configure the UE with up to four DL BWPs, but only one DL BWP can be active at a given time. If the serving cell is configured with an uplink (UL), the network configures at least one UL BWP. Similar to the DL, the network may configure the UE with up to four UL BWPs, but only one UL BWP can be active at a given time. NR also supports a so-called supplementary UL (SUL), on which UL BWP(s) can be similarly configured as on a normal UL. Other modifications are also contemplated herein.

In general, UE/CPE 705/706 communicating via the mobile network 701 only receive physical downlink shared channel (PDSCH), physical downlink control channel (PDCCH), or channel state information reference signal (CSI-RS) inside an active DL BWP. But the UE/CPE may need to perform radio resource management (RRM) measurements outside the active DL BWP via measurement gaps. Similarly, the UE/CPE only transmits physical uplink shared channel (PUSCH) or physical uplink control channel (PUCCH) inside an active UL BWP and, for an active serving cell, the UE/CPE does not transmit sounding reference signal (SRS) outside an active UL BWP.

Each network node 710 may include a Scheduler to implement uplink/downlink scheduling functions so as to allocate radio bearer resources to attached UE in accordance with appropriate QoS levels, which may comprise default QoS levels, QoS levels defined via Service Level Agreements (SLAs) of subscriber-associated with the UE, or some other mechanism. These radio bearer resources may be allocated in accordance with per-bearer QoS parameters such as QoS Class Identifiers (QCIs) which identify particular services or classes of services, Guaranteed Bit Rate (GBR) and/or Prioritized Bit Rate (PBR) which enable a determination as to specific radio bearers (e.g., specific UE) to accept, modify, or drop in response to a constrained resource condition, Allocation and Retention Policies (ARP) and the like. An Aggregate Maximum Bit Rate (AMBR) may be used to define a total bandwidth that may be utilized by a specific group of radio bearers (e.g., total bandwidth used supporting multiple network services associated with a one UE).

In various embodiments, network node 710 scheduling decisions are dynamically signaled on a L1/L2 physical downlink control channel (PDCCH), which may periodically (e.g., at a 1 ms transmission time interval) provide downlink schedule (DL-SCH) and/or uplink schedule (UL-SCH) information. Additional PDCCH information provided to the UE may comprise physical resource allocation, Modulation and Coding scheme, New-Data indicator, Transport Block size, Redundancy version, HARQ Process ID and the like. To avoid frequent signaling (i.e., every 1 ms) semi-persistent scheduling may also be employed, such as to define UL/DL resources for a radio bearer used for a periodic type of transmission, or a transmission of a known size or duration. For example, resources defined in terms of subcarriers, slots, resource blocks (RBs) and the like may be allocated to specific UE such as in accordance with a resource block map provided to UE via an uplink (UL) grant schedule.

The UE 705 may comprise any type of wireless device configured for use in accordance with the various embodiments, such as user terminals (e.g., mobile phones, laptops, tablets and the like), fixed wireless access devices (e.g., set top boxes, digital video recorders, stationary computing devices and the like), Internet of Things (IoT) devices (e.g., sensors, monitoring devices, alarm system devices and the like), and/or other wireless devices. The UE 705 may include UE that use licensed spectrum, unlicensed spectrum such as CBRS spectrum, or a combination of licensed and unlicensed spectrum. In the case of network nodes 710 having CBSD capability, allocations of CBRS spectrum are provided via SAS 770.

As depicted in FIG. 7, a Spectrum Access System (SAS) 770 communicates with the core network 720 (optionally with the DN 730) and is configured to control access to the CBRS frequency band for RANs and other CBSD devices such as network nodes 710, UE 705, and CPE 706. Generally speaking, the SAS 770 is configured to ensure that the CBRS frequency band is allocated for CBSD use, and that such use is adapted government requirements, network congestion, network interference and the like.

Various elements or portions thereof depicted in FIG. 7 and having functions described herein are implemented at least in part as computing devices having communications capabilities, including for example the UE 705, CPE 706, WAP 707, network nodes 710, SAS 770, UPF 740, and various network nodes and network functions of the core network 720. These elements or portions thereof have computing devices of various types, though generally a processor element (e.g., a central processing unit (CPU) or other suitable processor(s)), a memory (e.g., random access memory (RAM), read only memory (ROM), and the like), various communications interfaces (e.g., more interfaces enabling communications via different networks/RATs), input/output interfaces (e.g., GUI delivery mechanism, user input reception mechanism, web portal interacting with remote workstations and so on) and the like.

For example, various embodiments are implemented using network equipment used to implement network functions at a network core, network equipment comprising processing resources (e.g., one or more servers, processors and/or virtualized processing elements or compute resources) and non-transitory memory resources (e.g., one or more storage devices, memories and/or virtualized memory elements or storage resources), wherein the processing resources are configured to execute software instructions stored in the non-transitory memory resources to implement thereby the various methods and processes described herein. The network equipment may also be used to provide some or all of the various other core network nodes or functions described herein.

As such, the various functions depicted and described herein may be implemented at the elements or portions thereof as hardware or a combination of software and hardware, such as by using a general purpose computer, one or more application specific integrated circuits (ASIC), or any other hardware equivalents or combinations thereof. In various embodiments, computer instructions associated with a function of an element or portion thereof are loaded into a respective memory and executed by a respective processor to implement the respective functions as discussed herein. Thus various functions, elements and/or modules described herein, or portions thereof, may be implemented as a computer program product wherein computer instructions, when processed by a computing device, adapt the operation of the computing device such that the methods or techniques described herein are invoked or otherwise provided. Instructions for invoking the inventive methods may be stored in tangible and non-transitory computer readable medium such as fixed or removable media or memory or stored within a memory within a computing device operating according to the instructions.

### Exemplary Network Node Apparatus (710-1 of FIG. 7)

According to any of the embodiments herein, the node can be a software defined networking (SDN) node that is advantageously capable of supporting diverse RF interfaces such as DOCSIS, LTE, 4G, 5G, centrally controlled Wi-Fi, LoRa, and other RF network systems from a centralized location. This centralized node is sometimes referred to herein as a “chameleon node,” which may cooperatively operate with corresponding local and other remote network nodes that regenerate RF signals, such that a more flexible, adaptable, and agile multi-format/multi-function system is obtained. The innovative chameleon node embodiments herein may further advantageously leverage, in a scalable fashion. SDR, software defined MAC layers, various Split Architectures (e.g., MAC-PHY splits, slit PHY layer, split MAC), Network Function Virtualization (NFV), and virtual network functions (VNF), to implement the different networking personalities supported by the node.

According to any of the embodiments herein a node of the present application can be a gNB node that includes an open, virtualized Radio Access Network distributed unit (VDU) in communication with an open, virtualized Radio Access Network radio unit (VRU), as shown in FIG. 7 as node 710-1, for example, and also shown in FIGS. 8 and 9, with FIG. 8 being a more general view of the RU structure, and FIG. 9 providing more technical detail of the RU.

Referring to FIG. 8, the VDU is in communication with the VCU of the core network 720 and provides baseband 802 to a radio unit (RU) 806 of the node 710-1. The baseband 802 is a combination of a DOCSIS and 5G transmission and is transmitted path 804 to the RU 806 at either a wider bandwidth to extend over a 2 GHz wide bandwidth requirement, or wider, or the VDU can send up to 16 layers (or greater) of 200 Mhz wide channels (or wider) to create up to the 2 GHz wide bandwidth or wider.

This wide bandwidth is received at input 805 of the RU 806 and is then transmitted, along the transmission (TX) path to the digital front end (DFE) 808. The DFE 808 maps the bandwidth to multiple lanes and frequencies by receiving the I/Q samples and creating multiple layers with 400 MHz bandwidth per each path with 100 MHz CC, creating a total bandwidth support for 2500 MHz in this embodiment, in other embodiments an even larger total bandwidth support can be generated.

The multiple layers of signal are then up converted into the radio frequency front end (RFFE) 810, where the signals are amplified, and the power is uptilted per frequency band (400 MHz). The total bandwidth in the TX path of the RFFE 810 is 2500 MHz in this embodiment but can be greater or lesser in other embodiments.

Then the TX path is combined and can also, optionally be filtered. Then prior to exiting the TX path, the signals undergo sufficient and/or substantial impedance matching for loads in the 50-7562 range and can exit the RU 806 along a coaxial cable 812 to CPE 706.

Upon return from the CPE 706, through coaxial cable 812, the return signals can undergo impedance matching for loads in the 50-7502 range as the signals enter the RFFE 810. The return signals then enter the return transmission (RX) path and are diplexed and amplified within the RFFE 810. As the amplified signals in the RX path move from the RFFE 810 to the DFE 808 they are down converted, and then are mapped into I/Q streams within the DFE 808 and can then be transmitted out of the RU 806.

A more detailed view and explanation of FIG. 8 is shown in FIG. 9. Although not shown in FIG. 8 or FIG. 9, the RU 806 can include any suitable connectors and/or interfaces for connecting to outbound and incoming signals and cables.

Thus, FIG. 9 illustrates the RU 808 which receives an input from the vDU baseband 802, the RU 808 maps the input to multiple lanes depending on bandwidth and maps the lanes to the right frequency. The signal lanes are converted to analog, combined, and then matched to about 7552 impedance. The output of the RU 808 is transmitted to CPE via coaxial cable 812, with the receiving CPE then demodulating the output of the RU 808. In some more detail, FIG. 9 illustrates the mapping of 100 MHz wide channels, which are converted to analogue from 1300 MHz to 2700 MHz. Each channel (100-400 MHz) wide can then be connected to different Power Amplifier's (PA) to provide different level of amplification depending on the frequency needed for propagation over the coaxial cable 812. These signals are then combined and transmitted over the coaxial cable 812.

In more detail, in FIG. 9, the vDU baseband 802 transmits I/Q streams, to the RU 806, from up to six different nodes or cells of any suitaffilter.

ble type, with the streams being 100 MHz bandwidth and 4×4 multiple-input multiple-output (MIMO). The I/Q streams can be transmitted from the vDU baseband 802 via, up to, four 25G fiber transceivers. The vDU baseband 802 can either send wider bandwidths to the RU 806 to cover 2 GHz plus bandwidth needs or send up to sixteen layers for 200 MHz wide channels to create up to the 2 GHz plus wide bandwidth to the RU 806.

The RU 806 can receive signals via either the Common Public radio Interface (CPRI) or ethernet CPRI (eCPRI) protocol via any suitable port that can interface with received signals, and can then transmit the received signals, in 100 MHz (or more, or less) component carrier (cc) signals to a Lower psychical layer (PHY) download module 809 of the DFE 808. The PHY download module 809 can map each of the 100 MHz cc signals to a same frequency, or, the PHY download module 809 can map each of the 100 MHz cc signals to different frequencies such that adjacent 100 MHz signals are offset from adjacent channels at the different frequencies.

When transmission from the vDU baseband 802 to the RU 806 occurs from six different nodes or cells across four different transmission lines (six cells, 4×4 MIMO, four transmission lines) 24 layer spatial streams (6 cells by 4 transmission lines) are processed in the DFE 808. However, in other embodiments, any number of layers of the spatial stream, such as 8 layers or more, 12 layers or more, 16 layers or more, 20 layers or more, or 24 layers or more can be transmitted from the vDU baseband 802. The DFE 808 converts the frequency domain to the time domain using any transformation, including an inverse Fast Fourier Transform (IFFT).

The 24 spatial streams are then assigned to a RF transceiver board in the DFE 808, with that RF transceiver board 813 comprising at least two Digital-to-Analog converters (DAC), DAC 814A and DAC 814B. In other embodiments three or more DACs can be included, with each receiving signals alternatingly. Of the 24 spatial streams (or at least 8 spatial streams, at least 12 spatial streams, etc.), every four carriers are digitally combined at the RF transceiver board 813 to create a 400 MHz time-domain signal. The 400 MHz time-domain signal is then sent to one of DAC 814A or DAC 814B. Then the next 400 MHz time-domain signal is generated and sent to the other of the DAC 814A or 814B.

As an example of this conversion of the 24 spatial streams, for example, the first four streams of the 24 spatial streams are digitally combined at the RF transceiver board 813 and are then sent to DAC 814A. Then, the second four streams of the 24 spatial streams are digitally combined at the at the RF transceiver board 813 and are then sent to DAC 814B. Optionally, then the third four streams of the 24 spatial streams are digitally combined at the RF transceiver board 813 and are then sent to DAC 814A, etc. The alternating transmission to one of the DAC 814A or 814B continues until all of the up to 24 spatial streams are digitally combined into the 400 MHz time-domain signals, which totals six 400 MHz time-domain signals.

The 400 MHz time-domain signals, which have been converted to analog, by DAC 814A and 814B, can then be optionally filtered using any suitable bandpass filter to remove unwanted frequencies. Then, the signal strength of the optionally filtered 400 MHz time-domain signals can be boosted by two or more power amplifiers 816A and 816B, in the RFFE 810, that correspond to DAC 814A and 814B, respectively. After power amplification, the signals are then combined in a suitable RF combiner 818.

After the RF combiner 818, which combines the outputs of the power amplifiers 816A and 816B, the impedance matching component 820 matches the impedance of the output of the RF combiner 818 to in the 50-7562 range transmits a 2400 MHz wideband spectrum out of the RU 806 via any suitable port, through coaxial cable 812 to CPE 706 (shown in FIG. 7).

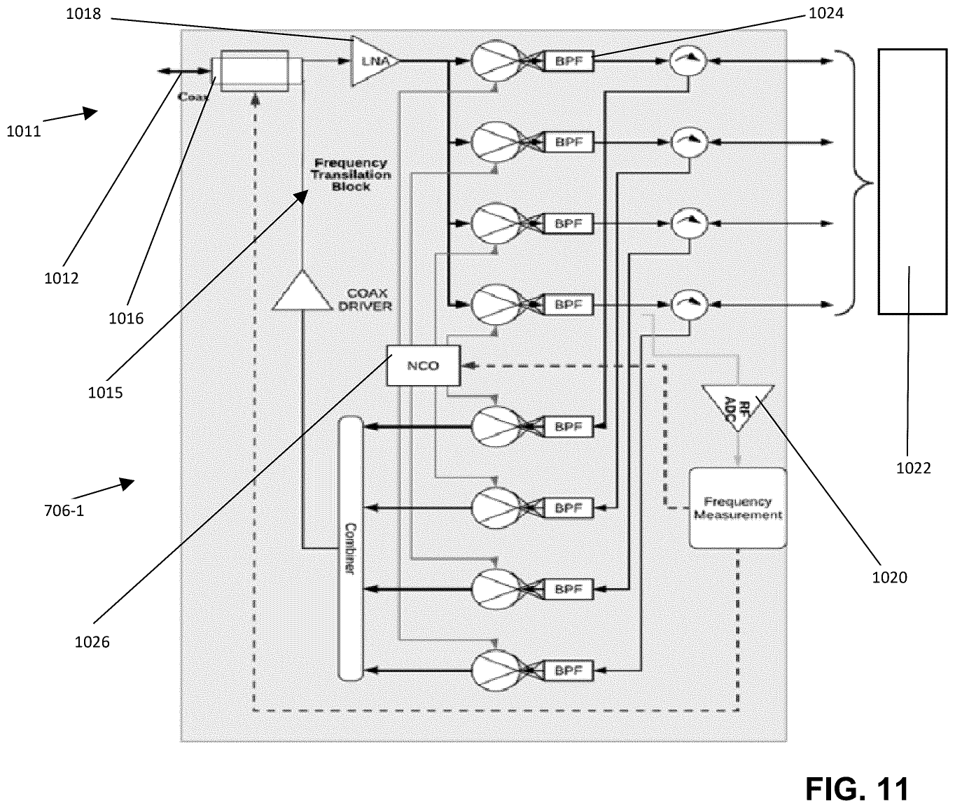

As can be seen in FIG. 10, one example of a CPE device 706-1 is shown. FIG. 10 provides a more general structure of the CPE device 706-1, with FIG. 11 providing a more specific structure of the CPE device 706-1. In FIG. 10, the CPE 706-1 receives an input from a suitable node (e.g. 710-1 of FIG. 7) over a coaxial cable 1012 via a suitable port. The coaxial cable 1012 can be any suitable coaxial cable (such as, for example a CommScope's P3® 500 cable, and/or an RG6 cable) can be any suitable distance from the node and one or more components of the network architecture (700 of FIG. 7) can be present between the CPE device 706-1 and the node. For example, one or more amplifiers (including bidirectional amplifiers, out of band (OOB) amplifiers, etc.), and/or one or more taps, etc.

In FIG. 10, the incoming signal over the coaxial cable 1012 enters the CPE 706-1 and undergoes impedance matching for loads in the 50-7562 range in an impedance matching component 1014. The incoming signal over the coaxial cable 1012 is transmitted from a vDU of the mobile network 701. The vDU can either transmit wider bandwidths to an RU of the mobile network 701, for subsequent transmission to CPE 706-1, to cover 2 GHz plus bandwidth needs, or send up to sixteen layers for 200 MHz wide channels to create up to the 2 GHz plus wide bandwidth to the RU of the mobile network 701, for subsequent transmission to CPE 706-1.

After the signal exits impedance matching component 1014, along the receiving (RX) path of a front end of the CPE 706-1 the signal is separated by diplexer and/or combiner device 1016, with the separated signal then being amplified in a low noise amplifier 1018 and then passing through a suitable down converter 1020.

After down conversion in the down converter 1020, the frequencies of the signals are mapped to multiple-input multiple-output (MIMO) layers or multiple component carriers (CC) and are then transmitted from the CEP 107-1 via any suitable modem 1022. The modem 1022 can transmit a signal in any suitable way, such as via an ethernet cable and/or wireless to various user equipment 705-1X (of FIG. 7).

A more detailed view of CPE 706-1 is shown in FIG. 11. FIG. 11 includes a head unit RF front end 1011 and a frequency translation block (FTB) 1015. In FIG. 11, the signal is received through coaxial cable 1012, the signal is then separated by diplexer and/or combiner device 1016, with the separated signal then being amplified in a low noise amplifier (LNA) 1018. In the structure illustrated in FIG. 11, there are up to 6 carrier components, each having 4 downlink (DL) (at or at about 100 MHz) and 2 uplink (UL) (at or at about 200 MHz) data streams.

The signal received by the CPE 706-1, after amplification by LNA 1018 the signal passes through one or more band pass filters (BPF) 1024 and through RF analog to digital converter 1020.

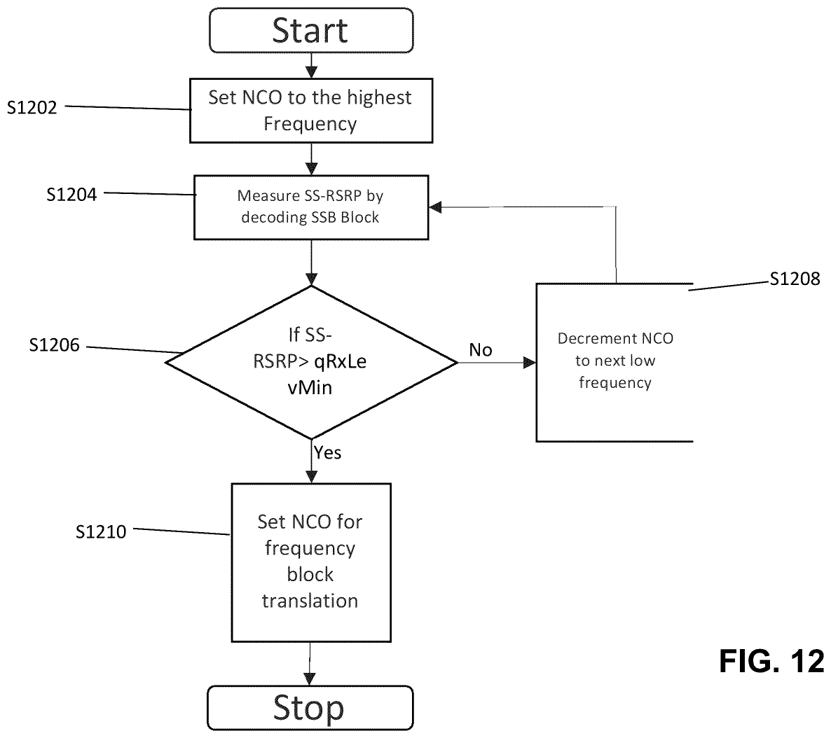

The FTB 1015 will consider the whole 2400 MHz frequency range received by the CPE 706-1 as 6*100 MHz (4×4 MIMO) signals. For this consideration, the FTB 1015 can comprise a cell search module and a frequency selector module that can operate according to the method discussed in reference to FIG. 12 herein. The FTB 1015 is operable to frequency translate (via one or more suitable translation modules) a received input signal to one of a plurality of different translational frequencies. Accordingly, the FTB 1015 is configured to output different frequency translated versions of the supplied signal.

After the carrier is selected from the six carrier components by the FTB 1015 (which is further described in reference to FIG. 12), wherein each of the carriers is a 100 MHz band out of the 400 MHz band, the frequency of the carrier is translated to a modem center frequency by a numerically controlled oscillator (NCO) 1026, into four separated paths. As an example of translation by the NCO, if the modem center frequency is, for example, 3700 MHz, the frequency selector module of the FTB 1015 converts the first 400 MHz which is from 1500 MHz-1900 MHz to 3700 Mhz as shown in Table 1 below.

TABLE 1

| | Carrier | | Modem |
|---|---|---|---|
| Carrier | Frequency | NCO | Central freq |
| CC#0 | 1500 | | |
| | 1550 | 2150 | 3700 |
| | 1600 | | |
| CC#1 | 1600 | | |
| | 1650 | 2050 | 3700 |
| | 1700 | | |
| CC#2 | 1700 | | |
| | 1750 | 1950 | 3700 |
| | 1800 | | |
| CC#3 | 1800 | | |
| | 1850 | 1850 | 3700 |
| | 1900 | | |

As per the design of FIG. 11 and Table 1, one example is when the six carrier components are 1500 Mhz, 1900 Mhz, 2300 Mhz, 2700 Mhz, Mhz 3100, 3500 MHz frequencies will carry single-sideband modulation (SSB). Therefore, CPE 706-1 will support 3CC (3 component carriers*400 MHz each) in DL and 2CC (2 component carriers*200 MHz each) in UL.

The method for selecting the correct frequency out of the wide bandwidth of up to 2,500 MHz to select the frequency with the highest signal strength, performed by the frequency selector module of the FTB 1015 and the NCO 1026 is discussed in reference to FIG. 12.

The method begins and at Step S1202, the NCO 1026 is set to the highest frequency in the signal. After that, in Step S1204, the synchronization signal reference signal received power (SS-RSRP) is measured in any suitable way, such as by decoding the Synchronization Signal block (SSB).

Then, in Step S1206 if the measured SS-RSRP is not greater than (S1206: NO) qRxLevMin, which represents a minimum receive strength of the reference signal received power (RSRP) by the CPE 706-1, the method proceeds to step S1208. At step S1208 the frequency the NCO 1026 was set at in S1202 is decremented to the next lowest frequency, and then the method continues to S1204 and again to S1206.

In Step S1206 if the measured SS-RSRP is greater than (S1206: YES) qRxLevMin, then the method proceeds to step S1210. At Step S1210 the NCO 1026 is set at the first frequency that results in (S1206: YES) for block translation and the CPE 706-1 will have selected the correct frequency received by the coaxial cable 1012.

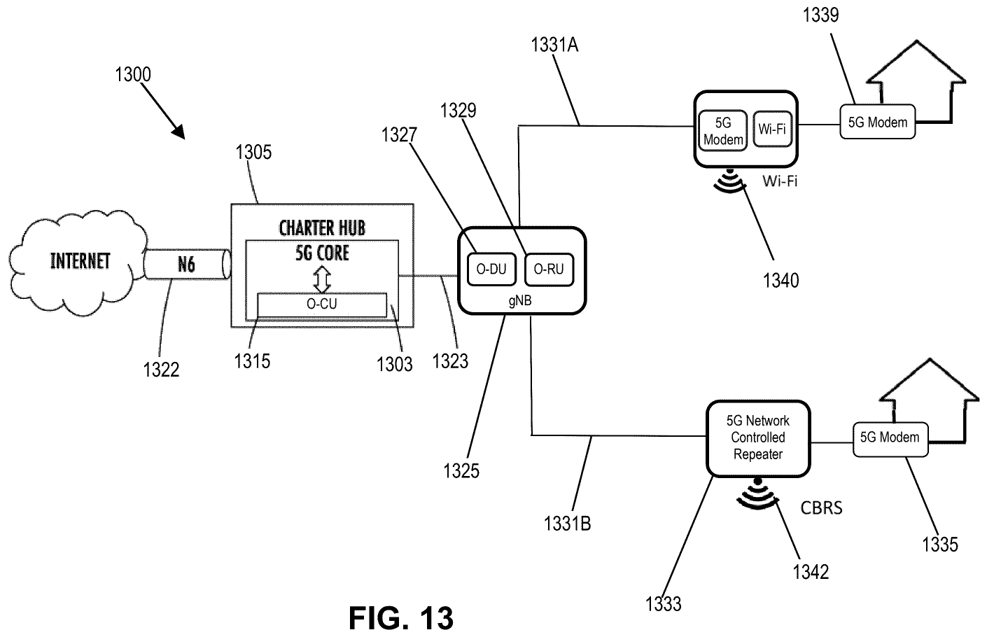

FIG. 13 depicts a block diagram of a network architecture benefitting from the various embodiments. The network architecture 1300 of FIG. 13 is depicted as, illustratively, a data center, or hub 1305 connected to the Internet over the extant N6 interface 1322. The hub includes a 5G New Radio (NR) Core 1303 that is configured to communicate with an open-control unit (O-CU) 1315. The hub 1305 can include a WLAN controller process, and services one or more nodes, with one node shown as a gNB node 1325 in FIG. 133.

The hub 1305 is configured to transmit a suitable signal to a node 1325 via any suitable strand, such as cable 1323. Cable 1323 is any suitable optical fiber and/or coaxial cable.

The node 1325 is any suitable node, such as an “enhanced” NR-based gNB architecture, which can be configured to utilize existing infrastructure (e.g., at least a portion of the extant HFC cabling controlled by an MSO such as the Assignee hereof) while expanding the frequency spectrum used for signal propagation within the infrastructure (e.g., greater than 1.6 GHz in total bandwidth). Moreover, access points or nodes installed at venues or premises, including “edge”-based nodes (at least some of which may be controlled, licensed, installed, or leased by the MSO), may be leveraged to deliver 5G-based services to a subscriber of the 5G NR Core 1303. Such networking made possible through this leveraged infrastructure allows a subscriber to access receive and maintain 5G service whether indoor or outdoor, and in fact, even while the subscriber is changing locations, e.g., moving indoor to outdoor, outdoor to indoor, between servicing nodes indoors (e.g., within a large house, office or housing complex, or venue), and between servicing nodes outdoors.

The hub 1305 comprises both the 5G NR core 1303 and the O-CU 1315, which may be an enhanced CU (CUe). The hub 1305 includes these components logically (but not necessarily physically) and is in communication with the open distributed unit (O-DU) 1327 of node 1325 to relay data and content. The O-DU 1327 can also be combined or integrated to varying degrees as well, with each node 1325 both an O-DU 1327 and an open radio unit “O-RU” 1329 logically and/or physically within the node 1325.

The node 1325 is configured to transmit a signal over a coaxial cable 1331A to a CPE 1337 that is connected to an outdoor antenna 1340 (or more than one outdoor antenna), the outdoor antenna 1340 configured to transmit a Wi-Fi signal outdoors.

The CPE 1337 can be a CPE capable of receiving radio frequency waveforms from network node 1325 and O-RU 1329 via the coaxial cable 1331A, in a coaxial cable network or a hybrid fiber/coaxial network (HFC). As used herein, CPE refers without limitation to any type of electronic equipment located within a customer's or subscriber's premises and connected to or in communication with the network 1300. Thus, CPE 1337 can include any equipment in the “customers' premises” (or other appropriate locations) that can be accessed by the relevant upstream network components, such as O-RU 1329 via the coaxial cable 1331A. Non-limiting examples of CPE are television (TV) sets/Smart TV's, set-top boxes, modems, personal video recorders (e.g. digital video recorder (DVR)), gateways, modems, personal computers (PCs), and minicomputers, whether desktop, laptop, or otherwise, and mobile devices such as handheld computers, PDAs, personal media devices (PMDs), tablets, “phablets”, smartphones, vehicle infotainment systems, and Advanced Wireless Gateways (AWGs) for providing high bandwidth Internet access in premises such as homes and businesses, or any portion and/or combination thereof.

The CPE 1337 can include a 5G modem 1339 in communication with a Wi-Fi transceiver 1341. The 5G modem 1339 can receive a suitable signal via coaxial cable 1331A and then transmit a signal in any suitable way, such as via an ethernet cable and/or wireless to various user equipment via the suitable Wi-Fi transceiver 1341. The signal received via the coaxial cable 1331A, transmitted from node 1325, is a signal spanning an expanded frequency spectrum to cover 2 GHz plus, or 2400 MHz plus, bandwidth needs, or up to sixteen layers for 200 MHz wide channels to create up to the 2 GHz plus, or 2400 MHz plus, wide bandwidth. The CPE 1337 is configured to receive this expanded frequency spectrum and transmit all or a portion of the bandwidth outdoors via outdoor antenna 1340.

CPE 1337 can also be configured to transmit all or a portion of the signal received via coaxial cable 1331A to 5G modem 1343, within an interior of a customer's premises, for suitable use within the customer premises.

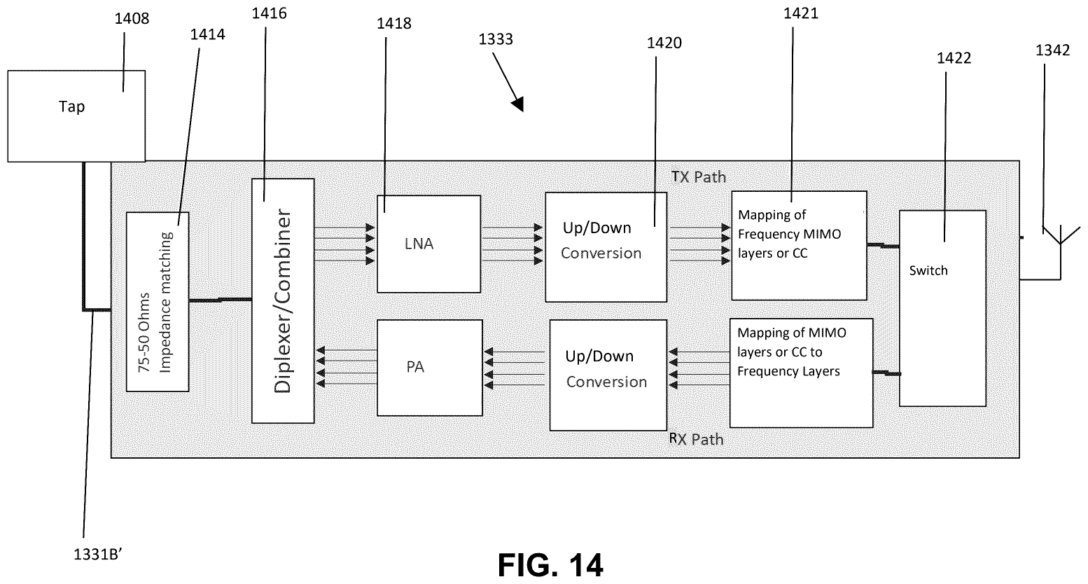

The node 1325 is configured to transmit a signal over a coaxial cable 1331B to a 5G Network Controlled Repeater “small cell” 1333. Although only one small cell is shown in FIG. 13, in other embodiments, two or more similar small cells can be connected to node 1325 via various coaxial cables. The small cell 1333 can be any external radio access node e.g., 3GPP “femtocell”), including a pole-mounted 5G-enabled remote radio head (RRH) with an associated Evolved Universal Terrestrial Radio Access Network (E-UTRAN) node. Small cell 1333 can leverage e.g., 3GPP unlicensed bands (such as NR-U bands in the 5 GHz range) or other spectrum such as CBRS (3.550-3.70 GHz, 3GPP Band 48), and C-Bands (3.30-5.00 GHz). Technologies for use of other bands such as 6 GHz band (5.925-7.125 GHz such as for Wi-Fi-6), and even mmWave bands (e.g., 24 GHZ and above). The small cell 1333 is discussed in more detail in reference to FIG. 14 herein.

The small cell 1333 is located in a backhaul portion of the network, and in this exemplary scenario, the backhaul is serviced by extant HFC infrastructure such as coaxial cable 1331B. The small cell 1333 is in data communication with both the O-RU 1329 and the O-DU 1327.

The signal received by the small cell 1333 via the coaxial cable 1331B, transmitted from node 1325, is a signal spanning an expanded frequency spectrum to cover 2 GHz plus, or 2400 MHz plus, bandwidth needs, or up to sixteen layers for 200 MHz wide channels to create up to the 2 GHz plus, or 2400 MHz plus, wide bandwidth. The small cell 1333 is configured to receive this expanded frequency spectrum and transmit all or a portion of the bandwidth outdoors via antenna 1342. Although not shown in FIG. 13, one or more taps can be present on coaxial cable 1331B, between the node 1325 and the small cell 1333.

Antenna 1342 is configured to transmit a 5G signal over the CBRS spectrum.

Small Cell 1333 can also be configured to transmit all or a portion of the signal received via coaxial cable 1331B to 5G modem 1335, within an interior of a customer's premises, for suitable use within the customer premises.

One advantage of the network architecture 1300 is that only one O-RU 1329 is present in the network architecture 1300, which is configured to transmit a signal to one or more small cells (such as small cell 1333) so that each small cell 1333 does not include a respective radio unit. Thus, architecture 1300 as well as other architecture disclosed herein can include one, single O-RU-1329 to transmit signals to two or more small cells 1333.

Various elements or portions thereof depicted in FIG. 13 and having functions described herein are implemented at least in part as computing devices having communications capabilities, including for example the node 1325, the O-DU 1327, the O-RU 1329, the small cell 1333 and the CPE 1337, and various network nodes and network functions of the hub 1305. These elements or portions thereof have computing devices of various types, though generally a processor element (e.g., a central processing unit (CPU) or other suitable processor(s)), a memory (e.g., random access memory (RAM), read only memory (ROM), and the like), various communications interfaces (e.g., more interfaces enabling communications via different networks/RATs), input/output interfaces (e.g., GUI delivery mechanism, user input reception mechanism, web portal interacting with remote workstations and so on) and the like.

For example, various embodiments are implemented using network equipment used to implement network functions at a network core, network equipment comprising processing resources (e.g., one or more servers, processors and/or virtualized processing elements or compute resources) and non-transitory memory resources (e.g., one or more storage devices, memories and/or virtualized memory elements or storage resources), wherein the processing resources are configured to execute software instructions stored in the non-transitory memory resources to implement thereby the various methods and processes described herein. The network equipment may also be used to provide some or all of the various other core network nodes or functions described herein.

As such, the various functions depicted and described herein may be implemented at the elements or portions thereof as hardware or a combination of software and hardware, such as by using a general purpose computer, one or more application specific integrated circuits (ASIC), or any other hardware equivalents or combinations thereof. In various embodiments, computer instructions associated with a function of an element or portion thereof are loaded into a respective memory and executed by a respective processor to implement the respective functions as discussed herein. Thus, various functions, elements and/or modules described herein, or portions thereof, may be implemented as a computer program product wherein computer instructions, when processed by a computing device, adapt the operation of the computing device such that the methods or techniques described herein are invoked or otherwise provided. Instructions for invoking the inventive methods may be stored in tangible and non-transitory computer readable medium such as fixed or removable media or memory, or stored within a memory within a computing device operating according to the instructions.

### Exemplary Small Cell (1306-1 of FIG. 13)

According to any of the embodiments herein, the small cell 1333 can have a structure shown in FIG. 14 and can receive a signal via one or more optional taps 1408. As seen in FIG. 14, the small cell 1333 receives a signal via a coaxial cable 1331B′, with coaxial cable 1331B′ extending from the tap 1408 to the small cell 1333.

Tap 1408 can be any suitable tap, such as a 2-way, 4-way or 8-way tap. The signal transmitted through the tap 1408, via the coaxial cable 1331B′ is received by the small cell 1333. The incoming signal over the coaxial cable 131B′ enters the small cell 1333 and undergoes impedance matching for loads in the 50-7562 range in an impedance matching component 1414. The incoming signal over the coaxial cable 1331B′ is transmitted from the O-RU 1329 (shown in FIG. 13). The O-RU 1329 can either transmit wider bandwidths to the small cell 1333 to cover 2 GHz plus bandwidth needs or send up to sixteen layers for 200 MHz wide channels to create up to the 2 GHz plus wide bandwidth from the O-RU 1329.

After the signal exits impedance matching component 1414, along the receiving (RX) path of the small cell 1333 the signal is separated by diplexer and/or combiner device 1416, with the separated signal then being amplified in a low noise amplifier 1418. After the signal is amplified by low noise amplifier and then passing through a suitable signal converter 1420. The signal converter 1420 is any suitable conversion element that is configured to increase and/or decrease the separated signal at the signal converter 1420 to an emission signal at the emission frequency needed to be radiated by the antenna 1342.

After the emission signal is converted to the frequency to be transmitted via antenna 1342, that converted frequency is mapped to two or more multiple-input multiple-output (MIMO) layers or multiple component carriers (CC) by a suitable transceiver node 1421 and are then transmitted from the small cell 1333 via the antenna 1342. The transceiver node 1421 is configured to map the converted frequencies to one or more MIMO layers (or CC) to converge at a destination, e.g. CPE or User Equipment (UE). In one embodiment, the two or more MIMO layers (or CC) are mapped to the frequency resources by the transceiver node 1421 based at least on channel quality feedback from the destination back to the small cell 1333. In another embodiment, the mapping can include the transceiver node 1421 selecting an appropriate modulation and coding scheme (MCS) for each of the MIMO layers.

Prior to transmission from the antenna 1342 of the signals mapped in the transceiver node 1421, the signals are transmitted through a switch 1422. Switch 1422 can be any suitable switch apparatus, such as a di-pole di-throw (DPDT) switch that is configured to activate a path to provide a feedback signal from the antenna 1342 through the receiving (Rx) path and to activate a path to provide a transmission signal from the transceiver node 1421 to the antenna 1342.

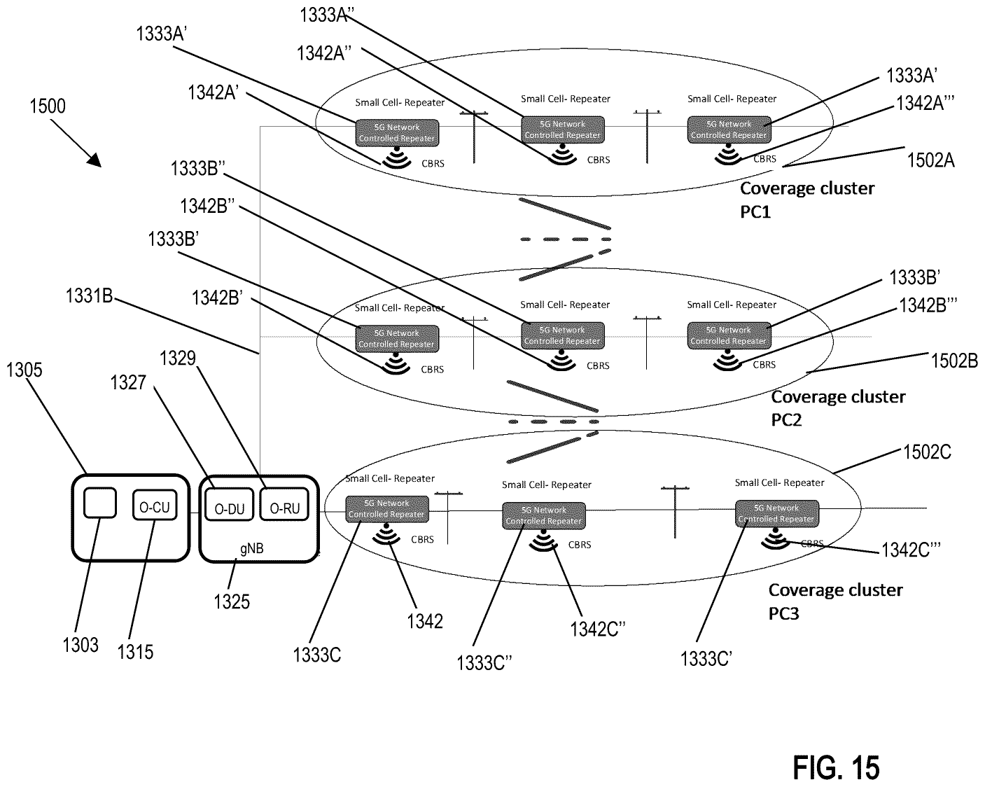

FIG. 15 depicts another embodiment, which is a block diagram of a network architecture 1300 for a plurality of small cell repeaters 1333. One small cell repeater 1333, and its respective antenna 1342, is shown in FIG. 13. Although not shown in FIG. 15, the architecture 1300, one or more taps 1408 can be included at one or more locations throughout the architecture 1300.

The network architecture 1300 can include a plurality of small cell repeaters 1333A′-1333C′″, and their respective antennas 1342A′-1342C′″, each receiving signals from one node 1325 and one radio unit O-RU 1329. Each of the plurality of small cell repeaters 1333 receives their respective signals from the one radio unit O-RU 1329 via coaxial cable 1331B, and then via other coaxial cables throughout the architecture 1300.

The plurality of small cell repeaters 1333 can be grouped into coverage clusters 1502A-1502C. For example, small cell repeaters 1333A′, 1333A″, and 1333A′″ are all within coverage cluster 1502A. Each coverage cluster can support the same physical call identification (PCI) for each repeater within the coverage cluster. For example, the small cell repeaters 1333A′, 1333A″, and 1333A′″ of coverage cluster 1502A can all be operating under the same PCI (“PC1” of FIG. 15) for user equipment (UE) within the respective cluster. Thus, no mobility is needed for the UE within each respective coverage cluster 1502A-1502C, with each UE sharing the same capacity within the respective coverage cluster 1502A-1502C. In the architecture 1500, capacity can be managed by dividing one or more of the coverage clusters 1502A-1502C to create an additional cluster with a different PCI, as needed or desired.

Since each respective cluster 1502A-1502C has their own same or differing capacities, mobility between each respective coverage cluster 1502A-1502C can be managed by handovers, which are managed at the node 1325.

Although three coverage clusters are shown in FIG. 15, in other embodiments, one, two four or more coverage clusters can be included in architecture 1500, with each cluster having the same or different number of small cell repeaters 1333. Additionally, even though each coverage cluster 1502A-1502C of architecture 1500 includes three small cell repeaters 1333, in other embodiments each coverage cluster 1502A-1502C can have the same or different number of small cell repeaters 1333, and can be one, two, four or more small cell repeaters. In the embodiment shown in FIG. 15, the coverage clusters 1502A-1502C do not overlap each other, however, in other embodiments, the coverage clusters 1502A-1502C can contact and/or overlap adjacent coverage clusters.

Each of the coverage clusters 1502A-1502C of architecture 1500 are areas of emission of RF signals from the antenna within each respective cluster. Although the emission clusters 1502A-1502C are illustrated as being an oval shape in architecture 1500, the shape of each emission cluster can be any shape and can be influenced by topography, structures, trees, etc., and each cluster can span indoor space and/or outdoor space. Each of the plurality of small cell repeaters 1333 in each respective coverage cluster 1502A-1502C is in relatively close proximity to create each respective coverage cluster 1502A-1502C.

Various modifications may be made to the systems, methods, apparatus, mechanisms, techniques and portions thereof described herein with respect to the various figures, such modifications being contemplated as being within the scope of the invention. For example, while a specific order of steps or arrangement of functional elements is presented in the various embodiments described herein, various other orders/arrangements of steps or functional elements may be utilized within the context of the various embodiments. Further, while modifications to embodiments may be discussed individually, various embodiments may use multiple modifications contemporaneously or in sequence, compound modifications and the like. It will be appreciated that the term “or” as used herein refers to a non-exclusive “or,” unless otherwise indicated (e.g., use of “or else” or “or in the alternative”).

Although various embodiments which incorporate the teachings of the present invention have been shown and described in detail herein, those skilled in the art can readily devise many other varied embodiments that still incorporate these teachings. Thus, while the foregoing is directed to various embodiments of the present invention, other and further embodiments of the invention may be devised without departing from the basic scope thereof.

1. A network architecture configured to transmit a coexisting signal of both a Data Over Cable Services Interface Specification (DOCSIS) signal and a 5G signal, the architecture comprising:
a node apparatus comprising:
a Distributed Unit (DU); and
a Radio Unit (RU) in communication with the DU, wherein the RU comprises:
a first port for interfacing with the coexisting signal transmitted from the DU, wherein the coexisting signal transmitted from the DU comprises at least an 8 layer spatial stream;
a Digital Front End (DFE) configured to process the spatial stream by combining a first four streams of the spatial stream in a first Digital to Analog (DAC) converter to form a first signal, and by combining a second four streams of the spatial stream in a second DAC, to form a second signal; and
a second port in communication with a coaxial cable, wherein the coaxial cable is configured to transmit the combined signal;
a customer premises equipment (CPE) apparatus, comprising:
a port to interface with the coaxial cable, the coaxial cable configured to transmit the coexisting signal; and
a modem configured to transmit to one or more user equipment.

2. The architecture of claim 1, wherein the node apparatus further comprises:
a first Power Amplifier (PA) configured to boost a signal strength of the first signal;
a second PA configured to boost a signal strength of the second signal;
a Radio Frequency (RF) combiner configured to combine the first signal and the second signal into a combined signal; and
an impedance matching component configured to sufficiently match the combined signal.

3. The architecture of claim 1, wherein the CPE further comprises:
an impedance matching component configured to sufficiently match the coexisting signal;
a diplexer configured to separate the coexisting signal into a separated signal;
a radio frequency (RF) analog to digital converter that is configured to convert the digital, separated signal into an analog signal;
a numerically controlled oscillator (NCO) connected to a frequency translation block (FTB), wherein the FTB comprises a frequency selector module that is configured to translate the analog signal into four separated paths and configured to convert the frequency of each of the separated paths based on a modem center frequency to a frequency selected signal.

4. The architecture of claim 1, further comprising a small cell apparatus comprising:
a port to interface with the coaxial cable, the coaxial cable configured to transmit the coexisting signal from the RU;
an impedance matching component configured to sufficiently match the coexisting signal;
a diplexer configured to separate the coexisting signal into a separated signal;
a signal converter configured to increase and/or decrease the separated signal to an emission signal at an emission frequency;
a transceiver node configured to map the emission signal to two or more multiple-input multiple-output (MIMO) layers; and
an antenna configured to transmit the two or more MIMO layers.

5. The architecture of claim 1, further comprising a filter configured to receive the coexisting signal from the node and configured to output the coexisting signal to the CPE.

6. The architecture of claim 1, wherein the at least 8 layer spatial stream is a 24 layer spatial stream that is converted from a frequency domain to a time domain by the RU.

7. The architecture of claim 1, wherein the first DAC outputs a first, analog, 400 MHz time-domain signal and the second DAC outputs a second, analog, 400 MHz time-domain signal.

8. The architecture of claim 1, further comprising an impedance matching component configured to match impedance for loads in a 50-7562 range.

9. The architecture of claim 1, wherein each layer of the spatial stream is mapped to a 100 MHZ wide channel.

10. The architecture of claim 1, wherein the signal transmitted from the DU comprises a 2 GHz wide bandwidth, or wider.

11. The architecture of claim 4, wherein the RU is a single RU.

12. The architecture of claim 4, wherein the two or more MIMO layers are mapped based on a channel quality feedback from a destination back to the small cell apparatus.

13. The architecture of claim 4, further comprising two or more small cell apparatus, wherein the two or more small cell apparatus comprise two or more coverage clusters.

14. The architecture of claim 13, wherein the two or more coverage clusters each comprise two or more small cell apparatus.

15. The architecture of claim 14, wherein each of the two or more coverage clusters comprises a physical call identification (PCI) that is different than a PCI of any of the other two or more coverage clusters.

16. The apparatus of claim 1, wherein the coaxial cable transmits up to a 2400 MHz wideband spectrum.

17. The apparatus of claim 16, wherein the 2400 MHz wideband spectrum is six 100 MHz 4×4 multiple-input multiple-output (MIMO) signals.

18. The apparatus of claim 1, wherein the apparatus is configured to manage 4 downlink (DL) signals at 100 MHz and 2 uplink (UL) signals at 200 MHz.

19. The apparatus of claim 3, wherein the FTB is configured to select the frequency of the analog signal with a highest signal strength.

20. The apparatus of claim 3, further comprising a low noise amplifier (LNA) configured to amplify the separated signal.
